(19) United States
(12) Patent Application Publication
(10) Pub. No.: US 2026/0026248 A1
(43) Pub. Date: Jan. 22, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: Jun Hee LEE, Yongin-si (KR); Yechan CHOI, Yongin-si (KR); Changwook KIM, Yongin-si (KR); Changhyun BACK, Yongin-si (KR); Minjung ANN, Yongin-si (KR)

(21) Appl. No.: 19/064,027

(22) Filed: Feb. 26, 2025

(30) Foreign Application Priority Data
Jul. 22, 2024 (KR) 10-2024-0096695

(51) Int. Cl. H10K 59/80; H10K 59/122

(52) U.S. Cl. CPC H10K 59/8792; H10K 59/122

(57) ABSTRACT

A display device may include an anode disposed on a substrate, a pixel defining layer provided with an opening exposing the anode, an upper surface of the pixel defining layer including a first high point, a second high point, and a low point therebetween, the first high point and the second high point being higher than the low point, and the low point corresponding to a lowest portion of the upper surface of the pixel defining layer between the first high point and the second high point, a first layer disposed on an upper surface of the anode, wherein the first high point overlaps an upper surface of the first layer, a light emitting layer disposed in the opening of the pixel defining layer, a cathode disposed on the light emitting layer and the pixel defining layer, and a light blocking area disposed on the pixel defining layer and overlapping the low point of the pixel defining layer.

### CROSS-REFERENCE TO RELATED APPLICATION

This application claims priority to and the benefit of Korean Patent Application No. 10-2024-0096695 filed at the Korean Intellectual Property Office on Jul. 22, 2024, the entire contents of which are herein incorporated by reference.

### BACKGROUND

### 1. Field

The present disclosure relates to a display device and an electronic device including the same.

### 2. Description of the Related Art

A display device is a device for displaying an image, and includes a liquid crystal display (LCD) or an organic light emitting diode (OLED) display. The display device is used in various electronic devices such as mobile phones, navigation devices, digital cameras, electronic books, portable game machines, and various terminals.

The display device such as a light emitting display device may have a structure in which the display device is bent or folded using a flexible substrate.

### SUMMARY

Embodiments are intended to provide a display device that does not include a polarizing plate and eliminates a disadvantage in which an inner pattern is visually recognized or a color is degraded by reflection of external light.

According to an aspect of the present disclosure, a display device may include a substrate, an anode disposed on the substrate, a pixel defining layer provided with an opening exposing the anode, an upper surface of the pixel defining layer including a first high point, a second high point, and a low point therebetween, the first high point and the second high point being higher than the low point, a first layer disposed on an upper surface of the anode, wherein the first high point overlaps an upper surface of the first layer, a light emitting layer disposed in the opening of the pixel defining layer, a cathode disposed on the light emitting layer and the pixel defining layer, and a light blocking area disposed on the pixel defining layer and overlapping the low point of the pixel defining layer.

At least a portion of the first layer may be spaced apart from the light blocking area when viewed in a plan view.

The low point may be disposed at least 1 micrometer from an inner edge of the light blocking area toward the second high point when viewed in a plan view.

The display device further includes a spacer spaced apart from a sidewall of the anode. The second high point overlaps an upper surface of the spacer, and the spacer and the first layer are formed of the same material.

The spacer and the first layer may be disposed below the upper surface of the pixel defining layer.

The light blocking area may include a light blocking opening. The first layer is formed of a closed loop with a first thickness when viewed in a plan view. The opening, the closed loop of the first layer, and the light blocking opening may be concentrically aligned when viewed in the plan view, with the first layer surrounding the opening, and the light blocking opening surrounding the first layer.

The display device may further include a red pixel, a green pixel, and a blue pixel disposed on the substrate, and the first layer overlaps at least one of the red pixel, the green pixel, and the blue pixel.

The light blocking area may include a light blocking layer including a light blocking material.

The light blocking area may correspond to a region where at least two color filters of different colors overlap.

According to an aspect of the present disclosure, a display device includes a substrate, an anode disposed on the substrate, a protective layer disposed on the anode, a pixel defining layer overlapping the anode and provided with a first opening exposing the anode and a second opening exposing the protective layer, a light emitting layer disposed within the first opening, a cathode disposed on the light emitting layer and the pixel defining layer, and a light blocking area disposed on the pixel defining layer and overlapping an exposed portion of the protective layer by the second opening.

The protective layer may include an organic material or an inorganic material.

A shortest distance between the second opening and an inner edge of the light blocking area may be at least 1 micrometer.

The light blocking area may include a light blocking opening. The second opening is formed of a closed loop with a first thickness when viewed in a plan view. The first opening, the light blocking opening, and the closed loop of the second opening are concentrically arranged when viewed in the plan view, with the light blocking opening surrounding the first opening, and the closed loop of the second opening surrounding the light blocking opening.

The display device may further include a red pixel, a green pixel, and a blue pixel disposed on the substrate, and the exposed portion of the protective layer may overlap at least one of the red pixel, the green pixel, and the blue pixel.

According to an aspect of the present disclosure, a display device includes a substrate, a first insulating layer disposed on the substrate, a second insulating layer disposed on the substrate and provided with an opening exposing the first insulating layer, an anode including a first portion disposed on an upper surface of the second insulating layer and a second portion disposed in the opening of the second insulating layer, a pixel defining layer provided with a first opening exposing the first portion of the anode and disposed on the second portion of the anode, wherein an upper surface of the pixel defining layer includes a first high point, a second high point, and a low point disposed therebetween, a light emitting layer disposed within the first opening of the pixel defining layer, a cathode disposed on the light emitting layer and the pixel defining layer, and a light blocking area disposed on the pixel defining layer and overlapping the low point of the pixel defining layer.

The low point may be disposed at least 1 micrometer from an inner edge of the light blocking area toward the second high point when viewed in a plan view.

The light blocking area may include a light blocking opening. The low point is formed of a closed loop when viewed in a plan view. The first opening, the light blocking opening, and the closed loop of the second high point are concentrically arranged when viewed in a plan view, with the light blocking opening surrounding the first opening, and the closed loop of the second high point surrounding the light blocking opening.

The display device further includes a red pixel, a green pixel, and a blue pixel disposed on the substrate. The opening of the second insulating layer and the low point overlap at least one of the red pixel, the green pixel, and the blue pixel.

According to an aspect of the present disclosure, an electronic device includes a processor, a memory having stored application programs for execution by the processor, a display device including a substrate, an anode disposed on the substrate, a pixel defining layer provided with an opening exposing the anode, wherein an upper surface of the pixel defining layer includes a first high point, a second high point, and a low point therebetween, wherein the first high point and the second high point are higher than the low point, a first layer disposed on an upper surface of the anode, wherein the first high point overlaps an upper surface of the first layer, a light emitting layer disposed in the opening of the pixel defining layer, a cathode disposed on the light emitting layer and the pixel defining layer, and a light blocking area disposed on the pixel defining layer and overlapping the low point of the pixel defining layer, and a user interface configured to sense user input via touch or cursor select of an icon presented on the display panel, wherein the processor is caused to execute one or more of the stored application programs upon receipt of the user input.

According to embodiments, a display device with improved display quality may be provided by reducing reflection and transmission of external light without including a polarizing plate.

### BRIEF DESCRIPTION OF THE DRAWINGS

FIG. 1 is a schematic perspective view showing a state of use of a display device according to an embodiment of the present disclosure.

FIG. 2 is an exploded perspective view of the display device according to an embodiment of the present disclosure.

FIG. 3 is a block diagram of the display device according to an embodiment of the present disclosure.

FIG. 4 is a perspective view schematically showing the display device according to an embodiment of the present disclosure.

FIG. 5 is an enlarged plan view of some areas of the display device according to an embodiment of the present disclosure.

FIG. 6 and FIG. 7 are cross-sectional views showing some areas of the display device according to an embodiment of the present disclosure.

FIG. 8 is a plan view schematically showing one pixel of the display device according to an embodiment of the present disclosure.

FIG. 9 is a cross-sectional view showing some components of the display device according to an embodiment of the present disclosure.

FIG. 10 is a plan view schematically showing one pixel of the display device according to an embodiment of the present disclosure.

FIGS. 11A and 11B are cross-sectional views of some components of the display device according to embodiments of the present disclosure.

FIG. 12 is a plan view showing some components of one pixel of the display device according to an embodiment of the present disclosure.

FIG. 13 is a plan view schematically showing a first repeating unit that is repeatedly disposed according to an embodiment of the present disclosure.

FIG. 14 is a cross-sectional view schematically showing components of some pixels according to an embodiment of the present disclosure.

FIGS. 15 to 21 are plan views schematically showing the first repeating unit that is repeatedly disposed according to an embodiment of the present disclosure.

FIGS. 22 to 26 are schematic cross-sectional views of the display device according to an embodiment of the present disclosure.

FIG. 27 is a block diagram illustrating an electronic device according to an embodiment of the present disclosure.

### DETAILED DESCRIPTION

Embodiments of the present disclosure will be described more fully hereinafter with reference to the accompanying drawings so that those skilled in the art could easily implement embodiments. The present disclosure may be modified in various ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

In the drawings, a size and a thickness of each element are arbitrarily illustrated for ease of description, and the present disclosure is not necessarily limited to those illustrated in the drawings. In the drawings, the thicknesses of some layers and areas are exaggerated for clarity. In the drawings, for ease of description, the thicknesses of some layers and areas are exaggerated.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” refers to placement relative to a referenced part, indicating a position either on or below it, regardless of the gravitational direction.

Unless explicitly stated to the contrary, the word “comprise” and variations such as “comprises” and “comprising” should be understood to imply the inclusion of stated elements but not the exclusion of any other elements.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

The present inventive concept relates to a display device that includes a pixel defining layer with an uneven upper surface. Unlike the present inventive concept, when a cathode is formed on a flat surface of the pixel defining layer, incident external light may be reflected from the flat surface and emitted in a front direction, thereby forming a reflection region (or a reflection band). The uneven upper surface of the pixel defining layer may reduce reflection of the external light by the cathode by directing the reflected light toward a light blocking area compared to the pixel defining layer with the flat upper surface. Additionally, the uneven upper surface of the pixel defining layer may be formed through a simple process using a first layer disposed on an upper surface of an anode.

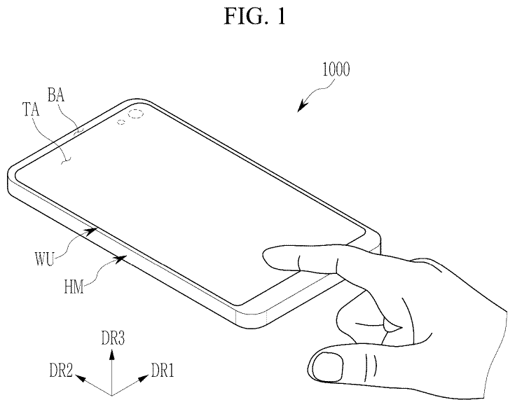

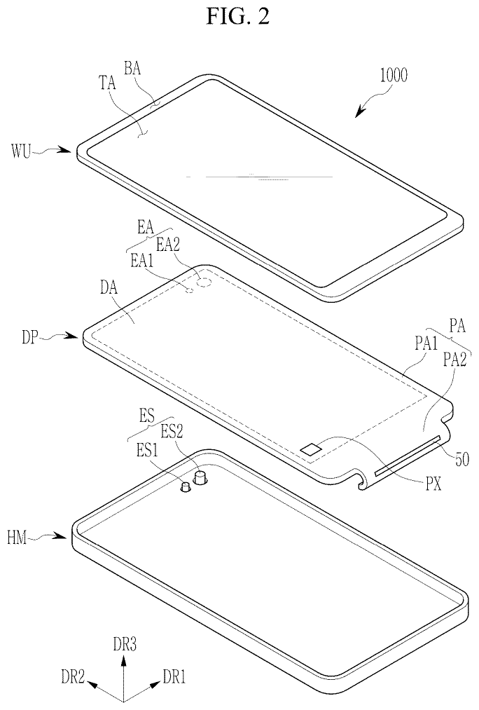

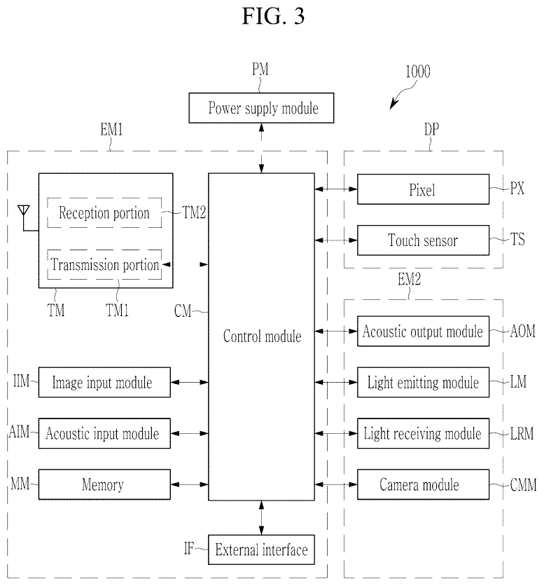

Hereinafter, a schematic structure of a display device will be described with reference to FIGS. 1 to 3. FIG. 1 is a schematic perspective view showing a state of use of a display device according to an embodiment, FIG. 2 is an exploded perspective view of the display device according to an embodiment, and FIG. 3 is a block diagram of the display device according to an embodiment.

Referring to FIG. 1, the display device 1000 according to an embodiment may display a moving image or a still image, and may be used for a display screen for a portable electronic device such as a mobile phone, a smart phone, a tablet personal computer (PC), a mobile communication terminal, an electronic notebook, an e-book, a portable multimedia player (PMP), a navigation device, and an ultra-mobile PC (UMPC), and various products such as a television, a laptop computer, a monitor, a billboard, and the Internet of things (IOT). The display device 1000 according to an embodiment may be used in a wearable device such as a smart watch, a watch phone, a glass-type display, and a head mounted display (HMD). The display device 1000 according to an embodiment may be used as a center information display (CID) disposed on a dashboard and a center fascia of a vehicle, a room mirror display in place of a side mirror of a vehicle, an entertainment for a rear seat of a vehicle, or a display disposed on a back of a front seat of a vehicle. For convenience of description, FIG. 1 shows the display device 1000 being used as a smart phone.

The display device 1000 may display an image in a third direction DR3 on a display surface parallel to a first direction DR1 and a second direction DR2. For example, the first direction DR1 and the second direction DR2 are parallel to an upper surface of the display surface, and the third direction DR3 is perpendicular to the display surface. The display surface on which the image is displayed may correspond to a front surface of the display device 1000, and may correspond to a front surface of a cover window WU. The image may include a still image as well as a dynamic image.

In the present embodiment, a front surface (or an upper surface) and a rear surface (or a lower surface) of each member are defined based on a direction in which the image is displayed. The front surface is opposite to the rear surface in the third direction DR3, and a normal direction of each of the front surface and the rear surface may be parallel to the third direction DR3. A separation distance between the front surface and the rear surface in the third direction DR3 may correspond to a thickness of a display panel in the third direction DR3.

The display device 1000 according to an embodiment may detect an input (e.g., an input by a hand of FIG. 1) of a user applied from the outside. The user's input may include various types of external inputs such as a portion of the user's body, light, heat, and pressure. In the embodiment of FIG. 1, the user's input is illustrated by the user's hand applied to the front surface. However, the present disclosure is not limited thereto.

The user's input may be provided in various forms, and the display device 1000 may sense the user's input applied to a side surface or a rear surface of the display device 1000 according to a structure of the display device 1000.

The display device 1000 may include the cover window WU and a housing HM. In an embodiment, the cover window WU and the housing HM may be coupled to form an appearance of the display device 1000.

The cover window WU may include an insulating panel. For example, the cover window WU may be made of glass, plastic, or a combination thereof.

A front surface of the cover window WU may define the front surface of the display device 1000. A transmission area TA may be an optically transparent area. For example, the transmission area TA may be an area having a visible light transmittance of about 90% or more. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

A blocking area BA may define a shape of the transmission area TA. The blocking area BA may be adjacent to the transmission area TA, and may surround the transmission area TA. The blocking area BA may be an area having relatively low light transmittance compared with the transmission area TA. The blocking area BA may include an opaque material that blocks light. The blocking area BA may have a predetermined color. The blocking area BA may be defined by a bezel layer provided separately from a transparent substrate defining the transmission area TA, or may be defined by an ink layer formed by being inserted into or colored on a transparent substrate.

The housing HM may be coupled to the cover window WU. The cover window WU may be disposed on a front surface of the housing HM. The housing HM may be coupled to the cover window WU to provide a predetermined accommodation space.

The housing HM may include a material having a relatively high rigidity (i.e., may include a rigid material securing the cover window WU). For example, the housing HM may include glass, plastic, or metal, or a plurality of frames and/or plates made of a combination of glass, plastic, and metal. The housing HM may accommodate and stably protect components of the display device 1000 from external impact.

Referring to FIG. 1 and FIG. 2, the display panel DP and an optical element ES may be accommodated in the accommodation space provided between the housing HM and the cover window WU.

The display panel DP may include a pixel PX displaying an image and a driver (or a driving portion) 50, and the pixel PX may be disposed on a display area DA and a component area EA. The display panel DP may include a front surface including the display area DA and a non-display area PA. In an embodiment, each of the display area DA and the component area EA may be an area in which an image is displayed by including the pixel, and may be an area in which an external input is sensed by a touch sensor disposed above the pixel in the third direction DR3.

The transmission area TA of the cover window WU may at least partially overlap the display area DA and the component area EA of the display panel DP. For example, the transmission area TA may overlap a front surface of each of the display area DA and the component area EA, or may overlap at least a portion of each of the display area DA and the component area EA. Accordingly, the user may view the image through the transmission area TA, or may provide an external input based on the image. However, the present disclosure is not limited thereto. For example, an area in which the image is displayed and an area in which the external input is detected may be separated from each other in the third direction DR3.

The non-display area PA of the display panel DP may at least partially overlap the blocking area BA of the cover window WU. The non-display area PA may be an area covered by the blocking area BA. The non-display area PA may be adjacent to the display area DA, and may surround the display area DA. An image may not be displayed at the non-display area PA. A driving circuit and a driving wire may be disposed in the non-display area PA to drive the display area DA. The non-display area PA may include a first peripheral area PA1 disposed outside the display area DA, and a second peripheral area PA2 including the driver 50, a connection wire, and a bending area. In the embodiment of FIG. 2, the first peripheral area PA1 may be disposed on three sides of the display area DA, and the second peripheral area PA2 may be disposed on the remaining side of the display area DA.

In an embodiment, a portion of the non-display area PA of the display panel DP may be bent. In this case, a portion of the non-display area PA may face the rear surface of the display device 1000 so that the blocking area BA shown on the front surface of the display device 1000 is reduced. In FIG. 2, the second peripheral area PA2 may be bent and positioned on the rear surface of the display area DA, and subsequently assembled at the rear surface.

The component area EA of the display panel DP may include a first component area EA1 and a second component area EA2. The first component area EA1 and the second component area EA2 may be at least partially surrounded by the display area DA. Although the first component area EA1 and the second component area EA2 are illustrated as being spaced apart from each other, the present disclosure is not limited thereto, and at least a portion of the first component area may be connected to at least a portion of the second component area. Each of the first component area EA1 and the second component area EA2 may be an area in which the optical element ES of FIG. 2 (hereinafter also referred to as a component) using infrared light, visible light, or sound is disposed thereunder.

A plurality of light emitting diodes and a plurality of pixel circuit portions generating and transmitting a light emitting current to each of the plurality of light emitting diodes may be formed at the display area DA (hereinafter also referred to as a main display area) and the component area EA. One light emitting diode and one pixel circuit portion are referred to as the pixel PX. In the display area DA and the component area EA, one pixel circuit portion may be formed on a one-to-one basis with respect to one light emitting diode.

The first component area EA1 may include a transmission portion through which light or/and sound is transmitted, and a display portion including a plurality of pixels. The transmission portion may be disposed between adjacent pixels, and may include a layer through which light or/and sound is transmitted. In an embodiment, a layer in which light of a specific wavelength band (e.g., visible light) is not transmitted may overlap the first component area EA1. The pixel density (referred to as resolution) in the display area DA, which consists of normal pixels, may be the same as the pixel density in the first component area (EA1), which consists of first component pixels. The number of pixels per unit area in the display area DA corresponds to the pixel density in the display area DA. The number of pixels per unit area in the first component area EA1 corresponds to the pixel density in the first component area EA1.

The second component area EA2 may include a transparent layer (hereinafter also referred to as a light transmitting area) to allow light to be transmitted. The light transmitting area may have a structure in which a conductive layer or a semiconductor layer is not disposed. A layer including a light blocking material (e.g., a pixel defining layer) and/or at least two color filters may be formed to include an opening overlapping a position corresponding to the second component area EA2 so as not to block light. The number of pixels per unit area of pixels included in the second component area EA2 (hereinafter also referred to as second component pixels) may be smaller than the number of pixels per unit area of the normal pixels included in the display area DA. As a result, the resolution of the second component pixels may be lower than the resolution of the normal pixels.

The driver 50 may be mounted on the second peripheral area PA2, and may be mounted on the bending portion or may be disposed on one of opposite sides of the bending portion. The driver 50 may be provided in a form of a chip.

The driver 50 may be electrically connected to the display area DA and the component area EA to transfer an electrical signal to pixels of the display area DA and the component area EA. For example, the driver 50 may provide data signals to the pixel PX disposed in the display area DA. Alternatively, the driver 50 may include a touch driving circuit, and may be electrically connected to a touch sensor TS (see FIG. 3) disposed in the display area DA and/or the component area EA. In addition to the above-described circuit, the driver 50 may include various circuits, or may be designed to provide various electrical signals to the display area DA.

A pad portion may be disposed on an end of the second peripheral area PA2 of the display device 1000, and the pad portion may be electrically connected to a flexible printed circuit board (FPCB) including a driving chip. The driving chip disposed on the flexible printed circuit board may include various driving circuits for driving the display device 1000 and a connector for power supply. According to an embodiment, a rigid printed circuit board (PCB) may be used instead of the flexible printed circuit board.

The optical element ES may be disposed below the display panel DP. The optical element ES may include a first optical element ES1 overlapping the first component area EA1 and a second optical element ES2 overlapping the second component area EA2. The first optical element ES1 may use infrared light, and in this case, a layer that does not transmit light such as visible light may overlap the first component area EA1.

The first optical element ES1 may be an electronic element using light or sound. For example, the first optical element ES1 may be a sensor (e.g., an infrared sensor) that receives and uses light, a sensor that outputs and senses light or sound to measure a distance or that recognizes a fingerprint, a small lamp that outputs light, or a speaker that outputs sound. The electronic element using light may use light of various wavelength bands such as visible light, infrared light, and ultraviolet light.

The second optical element ES2 may be at least one of a camera, an infrared camera, a dot projector, an infrared illuminator, and a time-of-flight sensor (ToF sensor).

In an embodiment, the optical element ES may additionally include a light sensing sensor or a heat sensing sensor. The optical element ES may detect an external subject received through a front surface thereof, or may provide a sound signal such as a voice through the front surface to the outside. The optical element ES may include a plurality of components, and is not limited to any one embodiment.

Referring to FIG. 3, the display device 1000 may include the display panel DP, a power supply module PM, a first electronic module EM1, and a second electronic module EM2. The display panel DP, the power supply module PM, the first electronic module EM1, and the second electronic module EM2 may be electrically connected to each other.

In FIG. 3, the pixel PX disposed on the display area DA and the touch sensor TS among configurations of the display panel DP are illustrated as examples. The display panel DP may include the pixel PX and the touch sensor TS. The display panel DP may include the pixel PX that is a component that generates an image so that the display panel is visually recognized by the user from the outside. The touch sensor TS may be disposed above the pixel PX, and may sense an external input. The touch sensor TS may detect the external input provided to the cover window.

The power supply module PM may supply power required for overall operation of the display device 1000. The power supply module PM may include a typical battery module.

The first electronic module EM1 and the second electronic module EM2 may include various functional modules for operating the display device 1000. The first electronic module EM1 may be directly mounted on a motherboard electrically connected to the display panel DP, or may be mounted on a separate substrate to be electrically connected to the motherboard through a connector (not shown).

The first electronic module EM1 may include a control module CM, a wireless communication module TM, an image input module IIM, an acoustic input module AIM, a memory MM, and an external interface IF. Some of the modules are not mounted on the motherboard, but may be electrically connected to the motherboard through a flexible printed circuit board connected thereto.

The control module CM may control overall operation of the display device 1000. The control module CM may be a microprocessor. For example, the control module CM may activate or deactivate the display panel DP. The control module CM may control other modules such as the image input module IIM and the acoustic input module AIM based on a touch signal received from the display panel DP.

The wireless communication module TM may transmit/receive a wireless signal to/from another terminal using Bluetooth or Wi-Fi. The wireless communication module TM may transmit/receive a voice signal using a general communication line. The wireless communication module TM may include a transmission portion TM1 that modulates and transmits a signal to be transmitted, and a reception portion TM2 that demodulates the received signal.

The image input module IIM may process an image signal to convert the processed image signal to image data displayable on the display panel DP. The acoustic input module AIM may receive an external sound signal by a microphone in a recording mode or a voice recognition mode to convert the received external sound signal to electrical voice data.

The external interface IF may serve as an interface connected to an external charger, a wired/wireless data port, or a card socket (e.g., a memory card or a SIM/UIM card).

The second electronic module EM2 may include an acoustic output module AOM, a light emitting module LM, a light receiving module LRM, or a camera module CMM and at least some of the acoustic output module, the light emitting module, the light receiving module, the camera module that are optical elements ES may be disposed on a rear surface of the display panel DP, as shown in FIG. 2. The optical elements ES may include the light emitting module LM, the light receiving module LRM, or the camera module CMM. The second electronic module EM2 may be directly mounted on the motherboard, may be mounted on a separate substrate to be electrically connected to the display panel DP through a connector (not shown), or may be electrically connected to the first electronic module EM1.

The acoustic output module AOM may convert audio data (or sound data) received from the wireless communication module TM or audio data stored in the memory MM to output the converted audio data to the outside.

The light emitting module LM may generate and output light. The light emitting module LM may output infrared light. For example, the light emitting module LM may include an LED element. For example, the light receiving module LRM may detect infrared light. The light receiving module LRM may be activated when infrared light of a predetermined level or more is detected. The light receiving module LRM may include a CMOS sensor. After the infrared light generated by the light emitting module LM is output, the output infrared light may be reflected by an external subject (e.g., the user's finger or face), and the reflected infrared light may be incident on the light receiving module LRM. The camera module CMM may capture an external image.

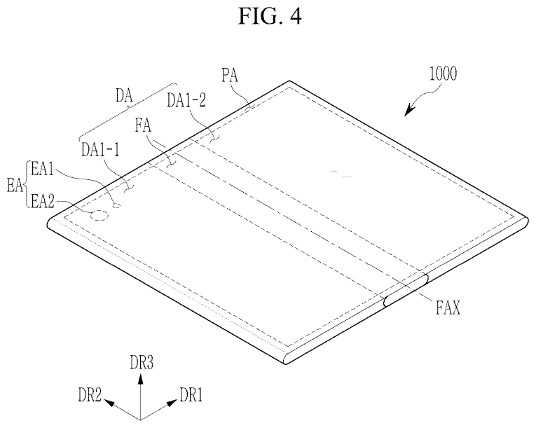

Hereinafter, a structure of the display device 1000 according to another embodiment will be described with reference to FIG. 4. FIG. 4 is a perspective view schematically showing the display device according to another embodiment. A description of the same components as those described above will be omitted, and in the embodiment of FIG. 4, a foldable display device having a structure in which the display device 1000 is folded through a folding axis (or a folding line) FAX is illustrated.

Referring to FIG. 4, in an embodiment, the display device 1000 may be the foldable display device. The display device 1000 may be folded outwardly or inwardly based on the folding axis FAX. When folded outwardly based on the folding axis FAX, display surfaces of the display device 1000 may be respectively disposed outside in the third direction DR3 to display images in both directions. When folded inwardly based on the folding axis FAX, the display surfaces may not be visually recognized from the outside.

In an embodiment, the display device 1000 may include a display area DA, a component area EA, and a non-display area PA. The display area DA may be divided into a (1-1)-th display area DA1-1, a (1-2)-th display area DA1-2, and a folding area FA. The (1-1)-th display area DA1-1 and the (1-2)-th display area DA1-2 may be respectively disposed on left and right sides with respect to (or at a center of) the folding axis FAX, and the folding area FA may be disposed between the (1-1)-th display area DA1-1 and the (1-2)-th display area DA1-2. In this case, when folded outwardly based on the folding axis FAX, the (1-1)-th display area DA1-1 and the (1-2)-th display area DA1-2 may be disposed on opposite sides in the third direction DR3 so that images are displayed in both directions. If folded inwardly based on the folding axis FAX, the (1-1)-th display area DA1-1 and the (1-2)-th display area DA1-2 may not be visible from the outside.

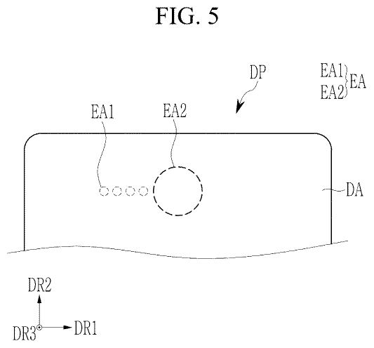

FIG. 5 is an enlarged plan view of some areas of the display device according to an embodiment. FIG. 5 illustrates a portion of the display panel DP of the display device according to an embodiment, and illustrates the portion of the display panel DP using a display panel for a mobile phone.

Referring to FIG. 5, the display area DA may be disposed on a front surface of the display panel DP, and the component area EA may also be disposed within the display area DA. For example, the component area EA may include the first component area EA1 and the second component area EA2. The first component area EA1 may be disposed on a position adjacent to the second component area EA2. In the embodiment of FIG. 5, a plurality of first component areas EA1 may be disposed to the left of the second component area EA2. A position and the number of the first component areas EA1 may vary according to an embodiment. In FIG. 5, a second optical element corresponding to the second component area EA2 may be a camera, and a first optical element corresponding to the first component area EA1 may be an optical sensor.

Although a structure of the light emitting display panel DP below a cutting line is not shown in FIG. 5, the display area DA may be disposed below the cutting line.

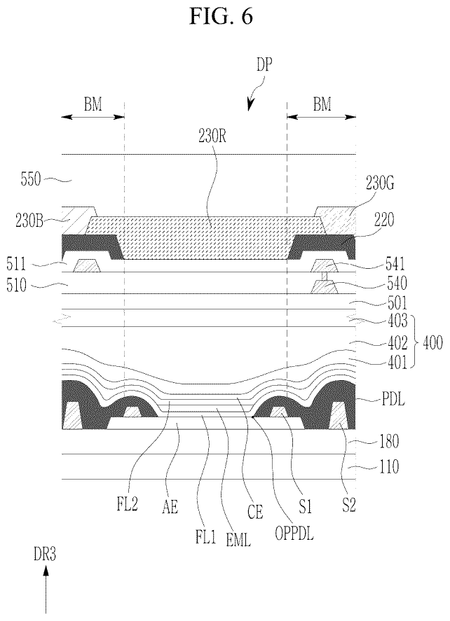

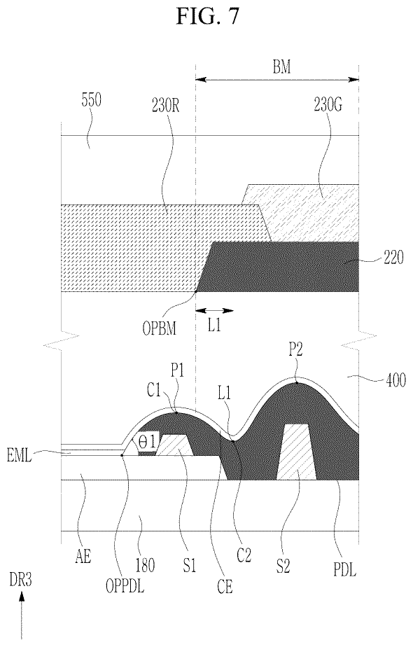

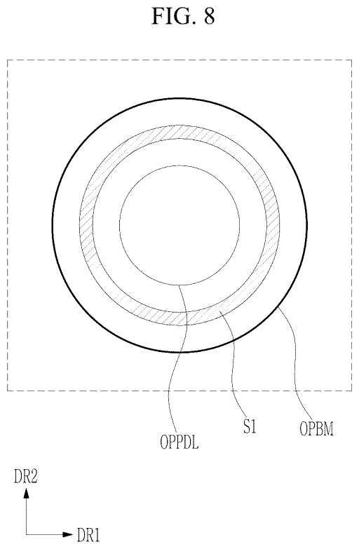

Hereinafter, a structure of the display panel according to an embodiment will be described with reference to FIGS. 6-8. FIG. 6 and FIG. 7 are cross-sectional views showing some areas of the display device according to an embodiment, and FIG. 8 is a plan view schematically showing one pixel of the display device according to an embodiment.

A stacking structure of the display panel DP according to an embodiment will be described with reference to FIG. 6.

The display panel DP may include a substrate 110. The substrate 110 may include a material (e.g., glass) that does not bend due to rigid characteristics, or a flexible material (e.g., a plastic or polyimide) that may bend.

A plurality of thin film transistors may be formed on the substrate 110, but they are omitted in FIG. 6, and only an insulating layer 180 covering the thin film transistors is shown. One pixel may include a light emitting diode, a plurality of transistors that transfer a light emitting current (i.e., a driving current) to the light emitting diode, and a capacitor. FIG. 6 does not illustrate the pixel circuit portion, and a structure of the pixel circuit portion may vary according to an embodiment. FIG. 6 shows the insulating layer 180 covering the pixel circuit portion.

The light emitting diode including an anode AE, a light emitting layer EML, and a cathode CE may be disposed above the insulating layer 180.

The anode AE may include a single layer including a transparent conductive oxide film and a metallic material, or multiple layers including the transparent conductive oxide film and the metallic material. The transparent conductive oxide film may include indium tin oxide (ITO), poly-ITO, indium zinc oxide (IZO), indium gallium zinc oxide (IGZO), or indium tin zinc oxide (ITZO), and the metallic material may include silver (Ag), molybdenum (Mo), copper (Cu), gold (Au), or aluminum (Al).

The light emitting layer EML may include a light emitting material, and adjacent light emitting layers EML may display different colors or the same color. In an embodiment, each of the light emitting layers EML may display a white light of the same color, and color filters passing different colors may be disposed on the light emitting layers EML. According to an embodiment, the light emitting layer EML may have a structure (also referred to as a tandem structure) in which a plurality of light emitting layers are stacked.

The pixel defining layer PDL may be disposed on the insulating layer 180 and the anode AE, and the pixel defining layer PDL may include a first opening OPPDL. The first opening OPPDL may expose a portion of the anode AE, and the light emitting layer EML may be disposed above the anode AE exposed by the first opening OPPDL. The light emitting layer EML may be disposed within the first opening OPPDL of the pixel defining layer PDL and may be spaced apart from an adjacent light emitting layer EML by the pixel defining layer PDL.

The pixel defining layer PDL may be formed of an organic material with a negative type of a black color. The organic material having a black color may include a light blocking material, and the light blocking material may include carbon black, carbon nanotube, a resin or a paste including a black dye, a metal particle (e.g., nickel, aluminum, molybdenum, or an alloy thereof), or a metal oxide particle (e.g., chromium nitride). The pixel defining layer PDL may include the light blocking material to have a black color, and may have the characteristic of absorbing/blocking light rather than reflecting it. Because the negative type uses an organic material, it may have a characteristic in which a portion covered by a mask is removed.

A first layer S1 and a spacer S2 may be disposed between the pixel defining layer PDL and the anode AE or between the pixel defining layer PDL and the insulating layer 180. The first layer S1 and the spacer S2 may be disposed below the pixel defining layer PDL.

The first layer S1 and the spacer S2 may be manufactured in the same process, and may include the same material. According to an embodiment, the first layer S1 and the spacer S2 may be formed of a positive-type photosensitive resin composition or a negative-type photosensitive resin composition. According to an embodiment, the first layer S1 and the spacer S2 may include the same material as that of the pixel defining layer PDL, or may include a heterogeneous material such as photosensitive polyimide (PSPI).

A first functional layer FL1 and a second functional layer FL2 may be disposed above the anode AE and the pixel defining layer PDL. The first functional layer FL1 and the second functional layer FL2 may be disposed on the front surface of the display panel DP, or may be disposed on all areas except for some areas (e.g., the light transmitting area of the second component area). The first functional layer FL1 may include at least one of a hole transport layer and a hole injection layer, and the second functional layer FL2 may include at least one of an electron injection layer and an electron transport layer. The hole injection layer, the hole transport layer, the light emitting layer EML, the electron transport layer, the electron injection layer, and the cathode CE may be sequentially disposed above the anode AE. The hole injection layer and the hole transport layer included in the first functional layer FL1 may be disposed below the light emitting layer EML, and the electron transport layer and the electron injection layer included in the second functional layer FL2 may be disposed above the light emitting layer EML.

The cathode CE may be a transparent electrode or a reflecting electrode. According to an embodiment, the cathode CE may be a transparent or semi-transparent electrode. The cathode CE may include a metal thin film with a small work function including lithium (Li), calcium (Ca), fluorinated lithium/calcium (LiF/Ca), fluorinated lithium/aluminum (LiF/Al), aluminum (Al), silver (Ag), magnesium (Mg), and a compound thereof. A transparent conductive oxide (TCO) film such as indium tin oxide (ITO), indium zinc oxide (IZO), zinc oxide (ZnO), and indium oxide (In₂O₃) may be further disposed on the thin metal film. The cathode CE may be integrally formed over the front surface of the display panel DP.

An encapsulation layer 400 may be disposed on the cathode CE. The encapsulation layer 400 may include at least one inorganic film and at least one organic film, and may have a triple-layer structure including a first inorganic encapsulation layer 401, an organic encapsulation layer 402, and a second inorganic encapsulation layer 403, as shown in FIG. 6. The encapsulation layer 400 may protect the light emitting layer EML formed of an organic material from moisture or oxygen that may be introduced from the outside. According to an embodiment, the encapsulation layer 400 may include a structure in which an inorganic layer and an organic layer are sequentially further stacked.

Sensing insulating layers 501, 510, and 511 and a plurality of sensing electrodes 540 and 541 may be disposed above the encapsulation layer 400 for touch sensing. In the embodiment of FIG. 6, a touch may be sensed in a capacitive type using two sensing electrodes 540 and 541, but according to an embodiment, a touch may also be sensed in a self-capacitive type using only one sensing electrode. The plurality of sensing electrodes 540 and 541 may be insulated from each other with the second sensing insulating layer 510 disposed therebetween, the lower sensing electrode 540 may be disposed on the first sensing insulating layer 501, the upper sensing electrode 541 may be disposed on the second sensing insulating layer 510, and the upper sensing electrode 541 may be covered by the third sensing insulating layer 511. The plurality of sensing electrodes 540 and 541 may be electrically connected through an opening disposed on the second sensing insulating layer 510.

The sensing electrodes 540 and 541 may include a metal such as aluminum (Al), copper (Cu), silver (Ag), gold (Au), molybdenum (Mo), titanium (Ti), tantalum (Ta), and a metal alloy thereof, and may include a single layer or multiple layers.

Color filters 230R, 230G, and 230B and a light blocking layer 220 may be disposed on the third sensing insulating layer 511.

The color filters 230R, 230G, and 230B may include the red color filter 230R that transmits red light, the green color filter 230G that transmits green light, and the blue color filter 230B that transmits blue light. Each of the color filters 230R, 230G, and 230B may overlap the anode AE of a corresponding light emitting diode when viewed in a plan view. Because light emitted from the light emitting layer EML has a corresponding color of the color filter, all light emitted from the light emitting layer EML may have the same color. In an embodiment, the light emitting layers EML may emit lights of different colors, and a displayed color may be enhanced by the color filter of the same color.

According to an embodiment, the color filters 230R, 230G, and 230B may be replaced with color conversion layers, or may further include color conversion layers. The color conversion layer may include a quantum dot.

A light blocking area BM may be disposed between adjacent color filters 230R, 230G, and 230B. According to an embodiment, the light blocking layer 220 may be disposed on the light blocking area BM. The light blocking layer 220 may be formed of an organic material having a black color. The organic material having black color may include a light blocking material.

A planarization layer 550 covering the color filters 230R, 230G, and 230B and the light blocking layer 220 may be disposed above the color filters 230R, 230G, and 230B and the light blocking layer 220. The planarization layer 550 may planarize an upper surface of the display panel, and may be a transparent organic insulating film including one or more materials selected from the group consisting of polyimide, polyamide, an acryl resin, benzocyclobutene, and a phenol resin.

According to an embodiment, a low-refractive index layer and an additional planarization layer may be further disposed on the planarization layer 550 to improve front visibility and light output efficiency of the display panel. Light may be refracted and emitted to the front by the low-refractive index layer and the additional planarization layer having a high-refractive index characteristic. In this case, according to an embodiment, the planarization layer 550 may be omitted, and the low-refractive index layer and the additional planarization layer may be directly disposed on the color filter.

In the present embodiment, a polarizing plate may not be included in an upper portion of the planarization layer 550. A display quality may be degraded because incident external light is reflected from the anode AE or a sidewall of the first opening of the pixel defining layer PDL so that the reflected light is visually recognized by the user, and the polarizing plate may serve to prevent the display quality from being degraded. However, the polarizing plate may have a disadvantage of consuming more power to display a certain luminance by reducing reflection of the external light as well as reducing light emitted from the light emitting layer EML. To reduce power consumption, the display device of the present embodiment may not include a polarizing plate.

Hereinafter, the pixel defining layer PDL and the first layer S1 according to an embodiment will be described in more detail with reference to FIG. 7 and FIG. 8. Hereinafter, only some components are illustrated, and a specific stacking relationship is described above with reference to FIG. 6.

Referring to FIG. 7, the anode AE and the pixel defining layer PDL may be disposed on the insulating layer 180.

The first layer S1 may be disposed between the anode AE and the pixel defining layer PDL. The first layer S1 and the spacer S2 may include the same material, and may be formed by the same process. For example, the first layer S1 and the spacer S2 may be manufactured in the same process using a halftone mask. A height of the first layer S1 may be smaller than a height of the spacer S2. For example, the height of the first layer S1 may be about 0.5 micrometer to about 1.0 micrometer. The height of the spacer S2 may be about 1.0 micrometer to about 2.0 micrometers. In an embodiment, an upper surface of the first layer S1 may be lower than an upper surface of the spacer S2, and a lower surface of the first layer S1 may be higher than a lower surface of the spacer S2.

The pixel defining layer PDL may be disposed on the first layer S1, the spacer S2, and the anode AE. The pixel defining layer PDL may include the first opening OPPDL that exposes a portion of the anode AE.

The pixel defining layer PDL may have a curved shape due to the first layer S1. For example, an upper surface of the pixel defining layer PDL may be uneven. The pixel defining layer PDL may include a first convex portion C1 protruding in the third direction DR3 by the first layer S1 and a first concave portion C2 connected to the first convex portion C1. The pixel defining layer PDL may have the first convex portion C1 in a portion overlapping the first layer S1, and the first concave portion C2 may be disposed to be connected to the first convex portion C1. The first convex portion C1 may include a portion disposed on the highest level of the pixel defining layer PDL that overlaps the first layer S1. The first concave portion C2 may be connected to the first convex portion C1, and may be disposed between the first layer S1 and the spacer S2. For example, the first convex portion C1 and the first concave portion C2 may be connected to form the uneven upper surface. In an embodiment, the uneven upper surface of the pixel defining layer PDL may include a first high point P1, a second high point P2, and a first low point L1 therebetween. In an embodiment, the first high point P1 and the second high point P2 may be higher than the first low point L1. In an embodiment, the first low point L1 may correspond to a lowest point or a lowest portion on the uneven upper surface, between the first high point P1 and the second high point P2, of the pixel defining layer PDL. The first high point P1 may be disposed on an upper surface of the first layer S1, and the second high point P2 may be disposed on an upper surface of the spacer S2. In an embodiment, the second high point P2 may be higher than the first high point P1 relative to an upper surface of the substrate 110. The first high point P1 may correspond to an uppermost point of the first convex portion C1. The first low point L1 may correspond to a lowest point or a lowest portion of the first concave portion C2. The second high point P2 may correspond to an uppermost point of another convex portion which is disposed on the upper surface of the spacer S2.

The first convex portion C1 may not overlap the light blocking layer 220. For example, the first high point P1 may be spaced apart from the light blocking layer 220 when viewed in a plan view. The first convex portion C1 may be spaced apart from the light blocking layer 220 in the third direction (or a thickness direction) DR3, and may overlap the color filter 230R. The first concave portion C2 or the first high point P1 may be disposed at least 1 micrometer inward from an inner edge of the light blocking layer 220 which defines a light blocking opening OPBM. For example, the first concave portion C2 or the first high point P1 may be disposed at least 1 micrometer from the inner edge of the light blocking layer 220 toward the second high point P2. A first distance L1 between the first concave portion C2 and a light blocking opening OPBM may be at least 1 micrometer when viewed in a plan view. The first concave portion C2 or the first low point L1 may stably overlap the light blocking layer 220.

A first height difference between the first convex portion C1 and the first concave portion C2 may be about 0.5 micrometer to about 1.0 micrometer. For example, the first height difference may correspond to a height difference between the first high point P1 and the first low point L1, and may be about 0.5 micrometer to about 1.0 micrometer. A second height difference between the second high point P2 and the first low point L1 may be about 1.0 micrometer to about 2.0 micrometers. The second height difference may be greater than the first height difference.

The shortest distance from an inner edge of the pixel defining layer PDL to an inner edge of the light blocking layer 220 may be at least 5 micrometers when viewed in a plan view, but may vary according to an embodiment. In an embodiment, the height difference between the first convex portion C1 and the first concave portion C2 of the pixel defining layer PDL may be about 0.3 micrometer to about 1 micrometer. An angle Θ1 of a tapered side surface of the inner edge of the pixel defining layer PDL may be about 15 degrees to about 35 degrees.

The anode AE and the cathode CE disposed on the light emitting layer EML may have a step difference according to the curved shape of the pixel defining layer PDL (i.e., the uneven upper surface of the pixel defining layer PDL). In this case, external light may be reflected in a direction of the light blocking layer 220 from the cathode CE disposed on a surface tapering from the first opening OPPDL of the pixel defining layer PDL to the first convex portion C1 and the first concave portion C2, so that reflection of the external light is hardly visible from the outside. Because the first concave portion C2 is covered by the light blocking layer 220, reliability of the pixel may be maintained even if a shape of the concave portion C2 changes due to a process error.

Referring to FIG. 8, the first layer S1 may be surrounded by the first opening OPPDL according to one embodiment. The first layer S1 may be surrounded by the light blocking opening OPBM of the light blocking layer 220. Sizes of the first opening OPPDL, the first layer S1, and the light blocking opening OPBM may increase in an order of the first opening OPPDL, the first layer S1, and the light blocking opening OPBM. For example, the first layer S1 may be formed of a closed loop having a predetermined thickness when viewed in a plan view, and the first opening OPPDL, the closed loop of the first layer S1, and the light blocking opening OPBM may be concentrically arranged so that the closed loop of the first layer S1 may surround the first opening OPPDL, and the light blocking opening OPBM may surround the closed loop of the first layer S1. In an embodiment, the first opening OPPDL, the closed loop of the first layer S1, and the light blocking opening OPBM may be circular.

The display device according to an embodiment may include the pixel defining layer PDL having a curved shape, so that reflection of external light caused by the cathode formed on a flat surface of the pixel defining layer PDL is reduced. For example, an upper surface of the pixel defining layer PDL may be uneven. A step difference of the pixel defining layer PDL may be induced through the first layer S1 disposed on the same layer as that of the spacer S2, so that the pixel defining layer PDL has a stably curved shape (i.e., the uneven surface) through a simple process.

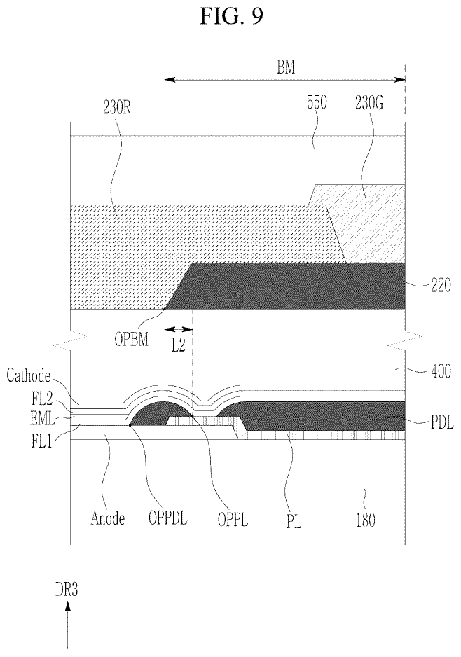

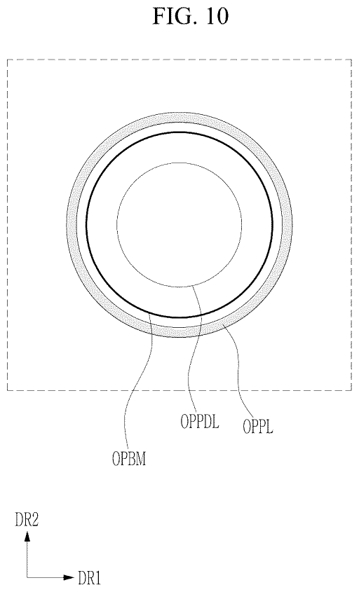

Hereinafter, a display device according to another embodiment will be described with reference to FIG. 9 and FIG. 10. FIG. 9 and FIG. 10 briefly illustrate components related to the pixel defining layer, the light blocking layer, and the color filter, and refer to FIG. 5 for a detailed stacking structure of other components.

Referring to FIG. 9, according to an embodiment, a protective layer PL may be disposed on the anode AE and the insulating layer 180. The protective layer PL may overlap at least a portion of the anode AE, and according to an embodiment, it may also be disposed on the insulating layer 180. The present disclosure is not limited thereto, and the protective layer PL may be disposed only on the anode AE.

The protective layer PL may include an organic material or an inorganic material. The protective layer PL may include any material for protecting the anode AE. According to an embodiment, the protective layer PL may include the same material as that of the pixel defining layer PDL, or may include a heterogeneous material such as photosensitive polyimide (PSPI).

A thickness of the protective layer PL may be about 0.5 micrometer to about 1.0 micrometer.

The pixel defining layer PDL may be disposed on the anode AE and the protective layer PL. The pixel defining layer PDL according to an embodiment may include the first opening OPPDL that exposes at least a portion of the anode AE. The pixel defining layer PDL according to an embodiment may include a second opening OPPL exposing a portion of the protective layer PL. The portion of the protective layer PL may be exposed by the second opening OPPL of the pixel defining layer PDL.

The second opening OPPL may overlap the light blocking layer 220 in cross-section. For example, the exposed portion of the protective layer PL by the second opening OPPL may overlap the light blocking layer 220. The second opening OPPL may be covered by the light blocking layer 220. The second opening OPPL may be disposed at least 1 micrometer inward from an inner edge of the light blocking layer 220. For example, a distance L2 between the second opening OPPL and the light blocking opening OPBM may be at least 1 micrometer when viewed in a plan view. The distance L2 may correspond to the shortest distance between the second opening OPPL and the light blocking opening OPBM when viewed in the plan view.

The first functional layer FL1 and the second functional layer FL2 may be disposed above the pixel defining layer PDL. The light emitting layer EML may be disposed within the first opening OPPDL. The first functional layer FL1 and the second functional layer FL2 disposed on a front surface of the substrate may also be disposed in the second opening OPPL of the pixel defining layer PDL. The first functional layer FL1 and the second functional layer FL2 may fill the second opening OPPL. According to an embodiment, the first functional layer FL1 may contact the exposed portion of the protective layer PL.

As shown in FIG. 10, sizes of the first opening OPPDL included in the pixel defining layer PDL, the light blocking opening OPBM included in the light blocking layer 220, and the second opening OPPL included in the pixel defining layer PDL may increase in an order of the first opening OPPDL, the light blocking opening OPBM, and the second opening OPPL. The light blocking opening OPBM may surround the first opening OPPDL. The second opening OPPL may surround the light blocking opening OPBM. For example, the second opening OPPL may be formed of a closed loop having a predetermined thickness when viewed in a plan view, and the first opening OPPDL, the light blocking opening OPBM, and the closed loop of the second opening OPPL may be concentrically arranged so that the light blocking opening OPBM may surround the first opening OPPDL, and the closed loop of the second opening OPPL may surround the light blocking opening OPBM. In an embodiment, the first opening OPPDL, the light blocking opening OPBM, and the closed loop of the second opening OPPL may be circular.

According to the embodiments of FIG. 9 and FIG. 10, the pixel defining layer PDL exposed by the light blocking layer 220 may have a curved shape. For example, an upper surface of the pixel defining layer PDL may be uneven. Therefore, even if external light is incident, the cathode CE disposed above the pixel defining layer PDL may be exposed to only a portion that has an inclined shape, and thus the external light reflected from the cathode CE with an inclined shape may be incident on the light blocking area so that reflection of the external light is hardly visible.

The anode AE may be exposed in a process in which the pixel defining layer PDL is manufactured to have this shape. The present embodiment may include the protective layer PL covering the anode AE to stably protect the anode AE. Thus, the present embodiment may provide the display device with improved reliability.

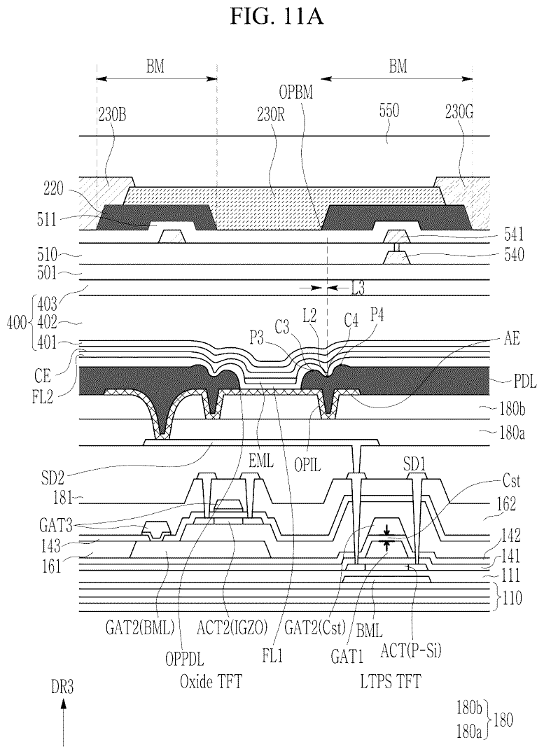

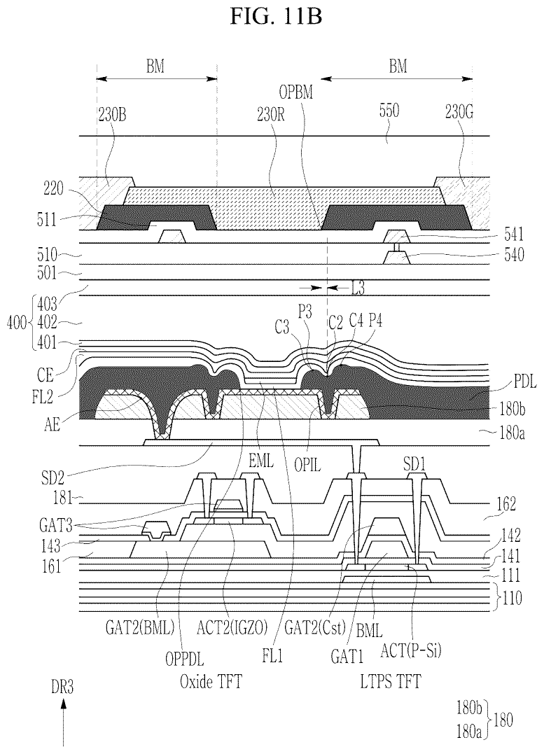

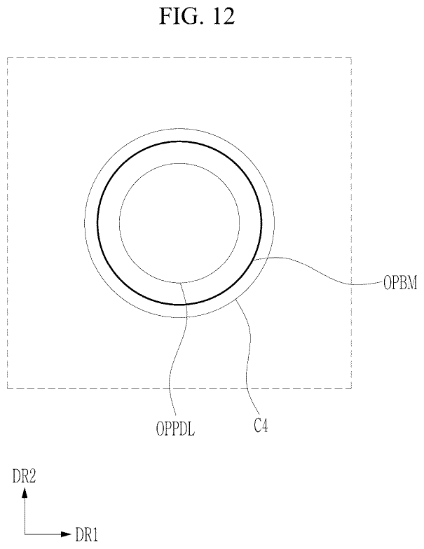

Hereinafter, a display device according to another embodiment will be described with reference to FIG. 11A, FIG. 11B, and FIG. 12. FIG. 11A and FIG. 11B are cross-sectional views of display devices according to an embodiment, and FIG. 12 is a plan view showing some components of one pixel. A description of the same components as those described above will be omitted.

Referring to FIG. 11A, a metal layer BML may be disposed on the substrate 110.

The substrate 110 may include a material (e.g., glass) that does not bend due to a rigid characteristic, or a flexible material (e.g., a plastic or polyimide) that bends. As shown in FIG. 11, the flexible substrate may have a structure in which a two-layer structure of polyimide and a barrier layer formed of an inorganic insulating material on the polyimide is doubly formed.

The metal layer BML may be disposed on a position that overlaps a channel of a driving transistor of a subsequent first semiconductor layer, and may also be referred to as a lower shielding layer. The metal layer BML may include a metal such as copper (Cu), molybdenum (Mo), aluminum (Al), titanium (Ti), and a metal alloy thereof.

A buffer layer 111 covering the substrate 110 and the metal layer BML may be disposed on the substrate 110 and the metal layer BML. The buffer layer 111 may serve to block penetration of an impure elements into the first semiconductor layer ACT(P-Si). The buffer layer 111 may be an inorganic insulating film including silicon oxide (SiOx), silicon nitride (SiNx), or silicon oxynitride (SiOxNy).

The first semiconductor layer ACT (P-Si) including a silicon semiconductor (e.g., a polycrystalline semiconductor (P-Si)) may be disposed on the buffer layer 111. The first semiconductor layer ACT (P-Si) may include a channel of a polycrystalline transistor LTPS TFT including the driving transistor and a first area and a second area disposed on either side of the channel. The polycrystalline transistor LTPS TFT may include various switching transistors or compensation transistors as well as the driving transistor. An area having a conductive layer characteristic may be provided on opposite sides of a channel of the first semiconductor layer ACT (P-Si) by plasma treatment or doping so that the area serves as each of a first electrode and a second electrode.

A first gate insulating film 141 may be disposed on the first semiconductor layer ACT (P-Si). The first gate insulating film 141 may be an inorganic insulating film including silicon oxide (SiOx), silicon nitride (SiNx), or silicon oxynitride (SiOxNy).

A first gate conductive layer including a gate electrode GAT1 of the polycrystalline transistor LTPS TFT may be disposed on the first gate insulating film 141. The first gate conductive layer may include a first scan line or a light emitting control line in addition to the gate electrode GAT1 of the polycrystalline transistor LTPS TFT. The first gate conductive layer may include a metal such as copper (Cu), molybdenum (Mo), aluminum (Al), titanium (Ti), or a metal alloy thereof, and may include a single layer or multiple layers.

After the first gate conductive layer is formed, an exposed area of the first semiconductor layer ACT(P-Si) may be made conductive by performing a plasma treatment or doping process. That is, the first semiconductor layer ACT(P-Si) covered by the first gate conductive layer may not be conductive, and a portion of the first semiconductor layer ACT(P-Si) that is not covered by the first gate conductive layer may have the same characteristic as that of the conductive layer.

A second gate insulating film 142 may be disposed on the first gate conductive layer and the first gate insulating film 141. The second gate insulating film 142 may be an inorganic insulating film including silicon oxide (SiOx), silicon nitride (SiNx), or silicon oxynitride (SiOxNy).

A second gate conductive layer including one electrode GAT2(Cst) of a storage capacitor Cst and a lower shielding layer GAT2(BML) of an oxide transistor Oxide TFT may be disposed on the second gate insulating film 142. The lower shielding layer GAT2(BML) of the oxide transistor Oxide TFT may be disposed below a channel of the oxide transistor Oxide TFT so that the lower shielding layer serves to shield the channel from light or electromagnetic interference provided from a lower side. The one electrode GAT2(Cst) of the storage capacitor Cst may overlap the gate electrode GAT1 of the driving transistor to form the storage capacitor Cst. According to an embodiment, the second gate conductive layer may further include a scan line, a control line, or a voltage line. The second gate conductive layer may include a metal such as copper (Cu), molybdenum (Mo), aluminum (Al), titanium (Ti), and a metal alloy thereof, and may include a single layer or multiple layers.

A first interlayer insulating film 161 may be disposed on the second gate conductive layer. The first interlayer insulating film 161 may include an inorganic insulating film including silicon oxide (SiOx), silicon nitride (SiNx), or silicon oxynitride (SiOxNy), and according to an embodiment, an inorganic insulating material may be thickly formed.

An oxide semiconductor layer ACT2(IGZO) including the channel, a first area, and a second area of the oxide transistor Oxide TFT may be disposed on the first interlayer insulating film 161.

A third gate insulating film 143 may be disposed on the oxide semiconductor layer ACT2(IGZO). The third gate insulating film 143 may be disposed on front surfaces of the oxide semiconductor layer ACT2(IGZO) and the first interlayer insulating film 161. The third gate insulating film 143 may include an inorganic insulating film including silicon oxide (SiOx), silicon nitride (SiNx), or silicon oxynitride (SiOxNy).

A third gate conductive layer GAT3 including a gate electrode of the oxide transistor Oxide TFT may be disposed above the third gate insulating film 143. The gate electrode of the oxide transistor Oxide TFT may overlap the channel. The third gate conductive layer GAT3 may further include a scan line or a control line, and may additionally include a connection member connected to the lower shielding layer GAT2(BML) of the oxide transistor Oxide TFT. The third gate conductive layer GAT3 may include a metal such as copper (Cu), molybdenum (Mo), aluminum (Al), titanium (Ti), or a metal alloy thereof, and may include a single layer or multiple layers.

A second interlayer insulating film 162 may be disposed on the third gate conductive layer GAT3. The second interlayer insulating film 162 may have a single-layer or multi-layer structure. The second interlayer insulating film 162 may include an inorganic insulating material such as silicon nitride (SiNx), silicon oxide (SiOx), and silicon oxynitride (SiOxNy). In an embodiment, the second interlayer insulating film 162 may include an organic material. In an embodiment, the second interlayer insulating film 162 may include a film of the inorganic insulating material and a film of the organic material.

A first data conductive layer SD1 including a connection member that may be connected to the first area and the second area of each of the polycrystalline transistor LTPS TFT and the oxide transistor Oxide TFT may be disposed on the second interlayer insulating film 162. The first data conductive layer SD1 may include a metal such as aluminum (Al), copper (Cu), molybdenum (Mo), titanium (Ti), and a metal alloy thereof, and may include a single layer or multiple layers.

A first organic film 181 may be disposed on the first data conductive layer SD1. The first organic film 181 may be an organic insulating film including an organic material, and the organic material may include one or more materials selected from the group consisting of polyimide, polyamide, an acryl resin, benzocyclobutene, and a phenol resin.

A second data conductive layer including an anode connection member SD2 may be disposed on the first organic film 181. The second data conductive layer may include a data line or a driving voltage line. The second data conductive layer may include a metal such as aluminum (Al), copper (Cu), molybdenum (Mo), titanium (Ti), and a metal alloy thereof, and may include a single layer or multiple layers.

The insulating layer 180 including a first insulating layer 180a and a second insulating layer 180b may be disposed on the second data conductive layer. The first insulating layer 180a and the second insulating layer 180b may include an opening for anode connection. The anode connection member SD2 may be electrically connected to the anode AE through the opening for anode connection. The first insulating layer 180a and the second insulating layer 180b may be an organic insulating film, and may include one or more materials selected from the group consisting of polyimide, polyamide, an acryl resin, benzocyclobutene, and a phenol resin.

At least one of the first insulating layer 180a and the second insulating layer 180b may include a third opening OPIL. The present specification has shown an embodiment in which the third opening OPIL is formed at the second insulating layer 180b, but the present disclosure is not limited thereto, and an embodiment in which the third opening is formed at the first insulating layer 180a or an embodiment in which both the first insulating layer 180a and the second insulating layer 180b include the third opening may also be possible.

According to an embodiment, a portion of the second insulating layer 180b may be island-shaped. A portion of the second insulating layer 180b overlapping the anode AE may be spaced apart from a continuously formed second insulating layer 180b to be island-shaped as shown in FIG. 11A.

The anode AE may be disposed on the second insulating layer 180b. The anode AE may be disposed in the third opening OPIL. The anode AE may have a step difference on the third opening OPIL. The anode AE may fill at least a portion of the third opening OPIL. For example, the anode AE may include a first portion disposed on an upper surface of the second insulating layer 180b and a second portion disposed in the third opening OPIL of the second insulating layer 180b. The second portion of the anode AE and the pixel defining layer PDL may fill the third opening OPIL.

The pixel defining layer PDL including the first opening OPPDL that exposes the anode AE may be disposed on the anode AE.

The pixel defining layer PDL may have a shape filling the step difference of the anode AE. For example, an upper surface of the pixel defining layer PDL may be uneven. A portion of the pixel defining layer PDL may be disposed on a portion in which the anode AE has the step difference to be connected to the anode connection member SD2, and a step difference portion in which the anode AE is formed within the third opening OPIL of the second insulating layer 180b.

The pixel defining layer PDL may include a second convex portion C3 and a second concave portion C4. The second convex portion C3 may be disposed adjacent to the first opening OPPDL of the pixel defining layer PDL, and the second concave portion C4 may be connected to the second convex portion C3. For example, the second concave portion C4 and the second convex portion C3 may be connected to form the uneven upper surface of the pixel defining layer PDL. In an embodiment, the uneven upper surface of the pixel defining layer PDL may include a third high point P3, a fourth high point P4, and a second low point L2 therebetween. In an embodiment, the third high point P3 and the fourth high point P4 may be higher than the second low point L2. In an embodiment, the second low point L2 may correspond to a lowest point or a lowest portion on the uneven upper surface, between the third high point P3 and the fourth high point P4, of the pixel defining layer PDL. The third high point P3 may be disposed on a portion of the anode AE between the third opening OPIL of the second insulating layer 180b and the light emitting layer EML when viewed in a plan view, and the fourth high point P4 may be disposed on an opposite portion of the anode AE with respect to the third opening OPIL. For example, the third high point P3 and the fourth high point P4 may be disposed on opposite sides of the third opening OPIL when viewed in the plan view. In an embodiment, the fourth high point P4 may be higher than the third high point P3 relative to an upper surface of the substrate 110. The third high point P1 may correspond to an uppermost point of the second convex portion C3. The second low point L2 may correspond to a lowest point or a lowest portion of the second concave portion C4.

The second concave portion C4 may overlap the light blocking layer 220. The second convex portion C3 may overlap or be spaced apart from at least a portion of the light blocking layer 220. The second concave portion C4 may be disposed at least 1 micrometer inward from the light blocking opening OPBM of the light blocking layer 220. A distance L3 between the second concave portion C4 and the light blocking opening OPBM (i.e., an inner edge of the light blocking layer 220) may be at least 1 micrometer. In an embodiment, the distance L3 may correspond to a shortest distance between the second low point L2 and the light blocking opening OPBM when viewed in a plan view.

As shown in FIG. 11B, a portion of the second insulating layer 180b may be removed. That is, the second insulating layer 180b may overlap the anode AE, and the portion of the second insulating layer 180b that does not overlap the anode AE in FIG. 11A may be removed.

The pixel defining layer PDL disposed on the second insulating layer 180b may cover an end of the second insulating layer 180b. The pixel defining layer PDL covering the end of the second insulating layer 180b may be disposed on a lower level than that of the pixel defining layer PDL disposed on the second insulating layer 180b. According to an embodiment, a portion of the pixel defining layer PDL may also contact the first insulating layer 180a.

As shown in FIG. 12, on a plane, the sizes of the first opening OPPDL of the pixel defining layer PDL, the light blocking opening OPBM of the light blocking layer 220, and the second concave portion C4 may increase in an order of the first opening OPPDL of the pixel defining layer PDL, the light blocking opening OPBM of the light blocking layer 220, and the second concave portion C4. The first opening OPPDL may be surrounded by the light blocking opening OPBM of the light blocking layer 220. The third opening OPIL of the second insulating layer 183 may be surrounded by the second concave portion C4. For example, the second concave portion C4 may be formed of a closed loop having a predetermined thickness when viewed in a plan view, and the first opening OPPDL, the light blocking opening OPBM, and the closed loop of the second concave portion C4 may be concentrically arranged so that the light blocking opening OPBM may surround the first opening OPPDL, and the closed loop of the second concave portion C4 may surround the light blocking opening OPBM. In an embodiment, the first opening OPPDL, the light blocking opening OPBM, and the closed loop of the second concave portion C4 may be circular.

According to the embodiments of FIG. 11A, FIG. 11B, and FIG. 12, the pixel defining layer PDL may be disposed above the third opening OPIL to have a step difference that overlaps the third opening OPIL. Even if light incident from the outside is reflected from the cathode CE, light incident from the outside may be incident in a direction of the light blocking area, and thus the pixel defining layer PDL with the curved shape (i.e., the uneven upper surface of the pixel defining layer PDL) may prevent the reflected light from being visually recognized by the user. A process in which the insulating layer includes the third opening OPIL and a process in which the pixel defining layer PDL has the curved shape (i.e., an uneven upper surface) through the process in which the insulating layer includes the third opening OPIL may be simple and highly reliable, allowing the present embodiment to provide the display device with improved reliability.

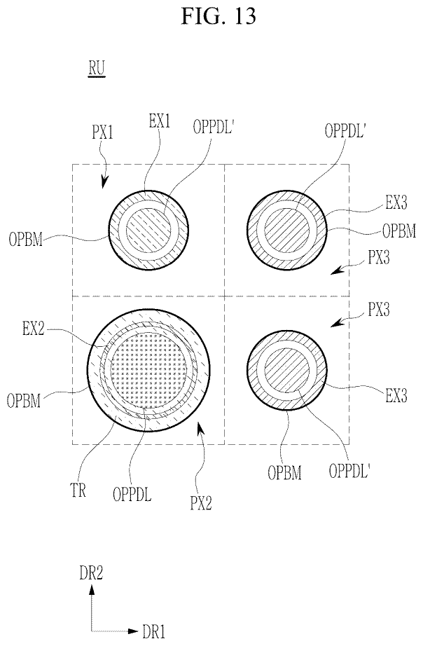

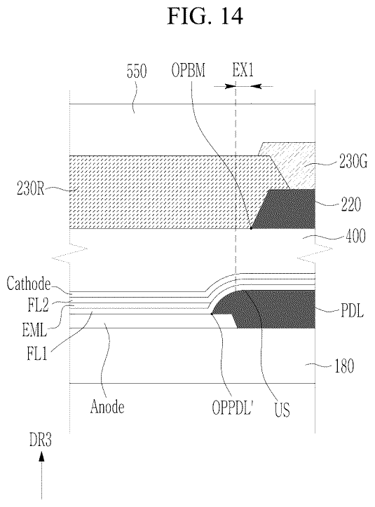

Hereinafter, a disposition of the pixel and a component included in each pixel according to an embodiment will be described with reference to FIGS. 13 to 21. FIGS. 13 and 15 to 20 are plan views schematically showing first repeating units that are repeatedly disposed, and FIG. 14 is a cross-sectional view schematically showing some pixels according to an embodiment. A description of the same components as those described above will be omitted.

Referring to FIG. 13, a first repeating unit RU may be repeatedly disposed in a matrix form above the display panel according to an embodiment. In this case, the first repeating unit RU may include two pixels of one color to include a total of four pixels PX1, PX2, and PX3. For example, the first repeating unit RU may include four adjacent pixels PX1, PX2, and PX3, and the four pixels PX1, PX2, and PX3 may include two pixels of a first color among three color pixels, and one each of the remaining pixels of a second color and a third color among the three color pixels. In an embodiment, two blue pixels PX3, one red pixel PX1, and one green pixel PX2 may be included among the four pixels PX1, PX2, and PX3.

Each of first openings OPPDL and OPPDL′ of the pixel defining layer PDL may have a circular shape, but the present disclosure is not limited thereto and may be modified into various shapes.

The first pixel PX1 and the second pixel PX2 may be disposed adjacent to each other in the second direction DR2, and two third pixels PX3 may be disposed adjacent to each other in the second direction DR2. The first pixel PX1 and the third pixel PX3 may be disposed adjacent to each other in the first direction DR1. The second pixel PX2 and the third pixel PX3 may be disposed adjacent to each other in the first direction DR1. However, the present disclosure is not limited thereto, and the first pixel PX1, the second pixel PX2, and the third pixel PX3 may be disposed in various shapes.

As shown in FIG. 13, the second pixel PX2 according to an embodiment may include a step difference structure TR. The step difference structure TR may include any one of the first structure including the first layer S1, the pixel defining layer PDL, and the light blocking area BM described with reference to FIG. 6, the second structure including the protective layer PL, the pixel defining layer PDL, and the light blocking area BM described with reference to FIG. 9, and the third structure including the second insulating layer 180b, the anode AE, the pixel defining layer PDL, and the light blocking area BM described with reference to FIG. 11.

The first pixel PX1 and the third pixel PX3 may not include a step difference structure. According to an embodiment, the first pixel PX1 and the third pixel PX3 may have a structure as shown in FIG. 14.

Referring to FIG. 14, according to an embodiment, the pixel defining layer PDL may be disposed on the anode AE. A side surface of the pixel defining layer PDL adjacent to the pixel opening OPPDL′ may have a tapered shape. A portion of a flat upper surface extending from the tapered side may not overlap the light blocking layer 220. Accordingly, the pixel defining layer PDL may overlap the color filter 230R, and may include an upper surface US of the pixel defining layer PDL spaced apart from the light blocking layer 220.

The cathode CE may be disposed above the upper surface US of the pixel defining layer PDL. External light may be reflected by the cathode CE with a flat shape to be emitted to the front, and may be visually recognized by the user. A reflection region EX1 surrounding the pixel opening OPPDL′ may be generated by the cathode CE in which the external light is easily reflected.

The display device according to an embodiment may apply the step difference structure TR to only the second pixel PX2 to reduce reflection of the external light generated from the second pixel PX2 and provide a color required by the user.

According to an embodiment, the second pixel PX2 may include a reflection region EX2. Even if the step difference structure TR is applied, reflection of the external light by the cathode CE may occur near the convex portion C1 of FIG. 7. The reflection of the external light by the cathode CE may occur at some areas of the pixel defining layer PDL that are not covered by the light blocking layer 220 of FIG. 9. The reflection of external light by the cathode CE may occur near the second convex portion C3 in FIG. 11A and FIG. 11B.

However, a thickness of the reflection region EX2 of the second pixel PX2 to which the step difference structure TR is applied may be smaller than thicknesses of reflection regions of the first pixel PX1 and the third pixel PX3 to which the step difference structure is not applied. According to an embodiment, an area of the reflection region may be small in the pixel to which the step difference structure is applied, and the area of the reflection region may be large in the pixel to which the step difference structure is not applied.

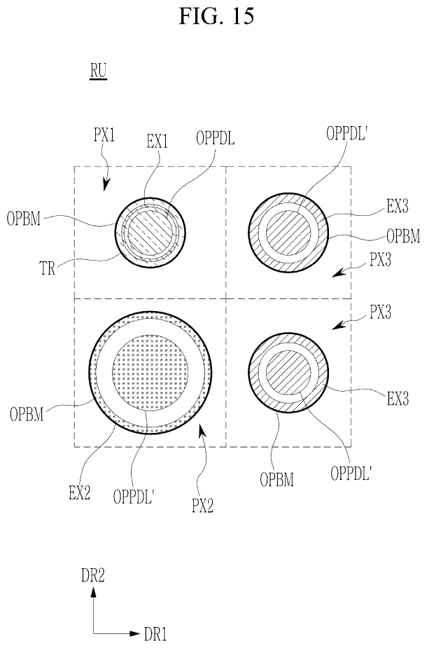

The reflection region EX2 included in the second pixel PX2 may be adjacent to the pixel opening OPPDL. The reflection region EX2 may be disposed adjacent to the pixel opening OPPDL compared with the reflection region EX1 included in the first pixel PX1 and the reflection region EX3 included in the third pixel PX3. The reflection region EX1 included in the first pixel PX1 and the reflection region EX3 included in the third pixel PX3 may be disposed relatively adjacent to the light blocking opening OPBM. Referring to FIG. 15, according to an embodiment, the step difference structure TR may be applied to the first pixel PX1 in the first repeating unit RU. The step difference structure TR may not be applied to the second pixel PX2 and the third pixel PX3.

The second pixel PX2 and the third pixel PX3 may have the cross-sectional structure shown in FIG. 14. The second pixel PX2 and the third pixel PX3 may include the reflection regions EX2 and EX3 surrounding the pixel opening OPPDL′. The first pixel PX1 may include the reflection region EX1 surrounding the pixel opening OPPDL.

A thickness of the reflection region EX1 of the first pixel PX1 to which the step difference structure TR is applied may be smaller than thicknesses of the reflection regions of the second pixel PX2 and the third pixel PX3 to which the step difference structure is not applied. That is, the reflection region may be reduced.

The reflection region EX1 included in the first pixel PX1 may be adjacent to the pixel opening OPPDL. The reflection region EX1 may be disposed adjacent to the pixel opening OPPDL compared with the reflection region EX2 included in the second pixel PX2 and the reflection region EX3 included in the third pixel PX3. The reflection region EX2 included in the second pixel PX2 and the reflection region EX3 included in the third pixel PX3 may be disposed relatively adjacent to the light blocking opening OPBM.

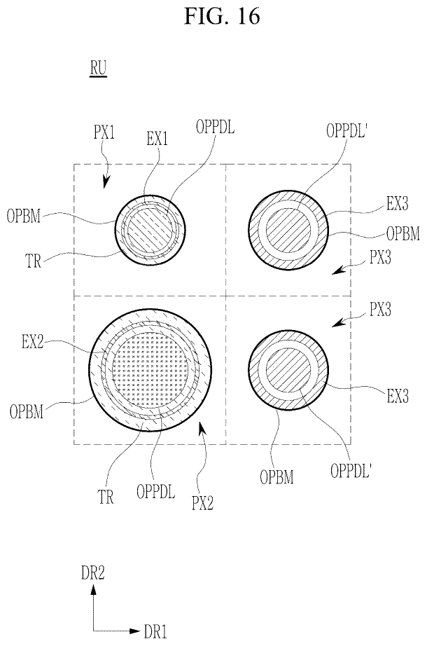

Referring to FIG. 16, according to an embodiment, the step difference structure TR may be applied to the first pixel PX1 and the second pixel PX2 in the first repeating unit RU. The step difference structure TR may not be applied to the third pixel PX3. The third pixel PX3 may have the cross-sectional structure shown in FIG. 14.

The third pixel PX3 may include the reflection region EX3 surrounding the pixel opening OPPDL′. The first pixel PX1 and the second pixel PX2 may include the reflection regions EX1 and EX2 surrounding the pixel opening OPPDL.

Thicknesses of the reflection regions EX1 and EX2 of the first pixel PX1 and the second pixel PX2 to which the step difference structure TR is applied may be smaller than a thickness of the reflection region EX3 of the third pixel PX3 to which the step difference structure is not applied.

The reflection regions EX1 and EX2 included in the first pixel PX1 and the second pixel PX2 may be relatively adjacent to the pixel opening OPPDL. The reflection region EX3 included in the third pixel PX3 may be disposed relatively adjacent to the light blocking opening OPBM.

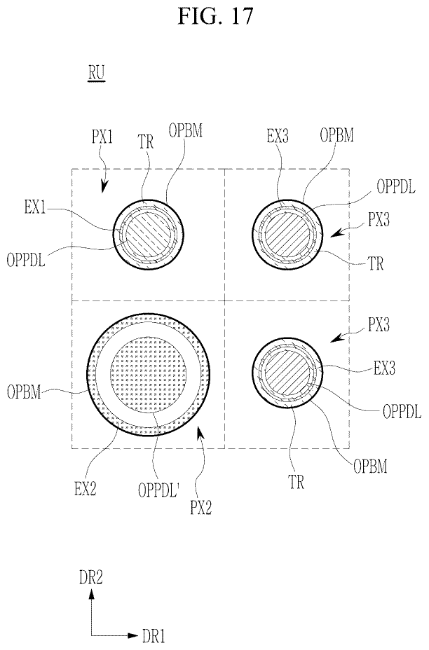

Referring to FIG. 17, according to an embodiment, the step difference structure TR may be applied to the first pixel PX1 and the third pixel PX3 in the first repeating unit RU. The step difference structure TR may not be applied to the second pixel PX2. The second pixel PX2 may have the cross-sectional structure shown in FIG. 14.

The second pixel PX2 may include the reflection region EX2 surrounding the pixel opening OPPDL′. The first pixel PX1 and the third pixel PX3 may include the reflection regions EX1 and EX3 surrounding the pixel opening OPPDL.

Thicknesses of the reflection regions EX1 and EX3 of the first pixel PX1 and the third pixel PX3 to which the step difference structure TR is applied may be smaller than a thickness of the reflection region EX2 of the second pixel PX2 to which the step difference structure is not applied.

The reflection regions EX1 and EX3 included in the first pixel PX1 and the third pixel PX3 may be relatively adjacent to the pixel opening OPPDL. The reflection region EX2 included in the second pixel PX2 may be disposed relatively adjacent to the light blocking opening OPBM.

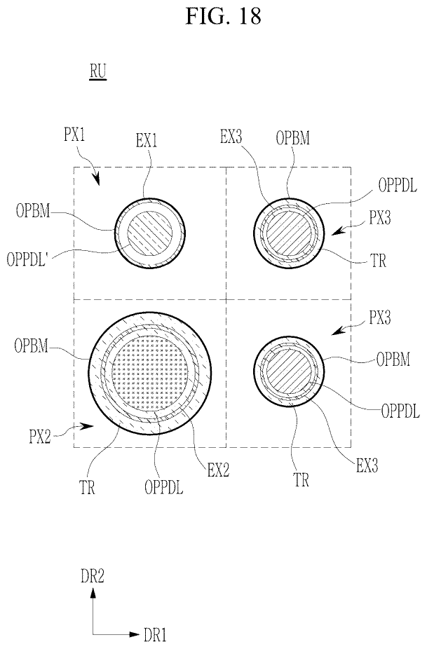

Referring to FIG. 18, according to an embodiment, the step difference structure TR may be applied to the second pixel PX2 and the third pixel PX3 in the first repeating unit RU. The step difference structure TR may not be applied to the first pixel PX1. The first pixel PX1 may have the cross-sectional structure shown in FIG. 14.

The first pixel PX1 may include the reflection region EX1 surrounding the pixel opening OPPDL′. The second pixel PX2 and the third pixel PX3 may include the reflection regions EX2 and EX3 surrounding the pixel opening OPPDL.

Thicknesses of the reflection regions EX2 and EX3 of the second pixel PX2 and the third pixel PX3 to which the step difference structure TR is applied may be smaller than a thickness of the reflection region EX1 of the first pixel PX1 to which the step difference structure is not applied.

The reflection regions EX2 and EX3 included in the second pixel PX2 and the third pixel PX3 may be relatively adjacent to the pixel opening OPPDL. The reflection region EX1 included in the first pixel PX1 may be disposed relatively adjacent to the light blocking opening OPBM.

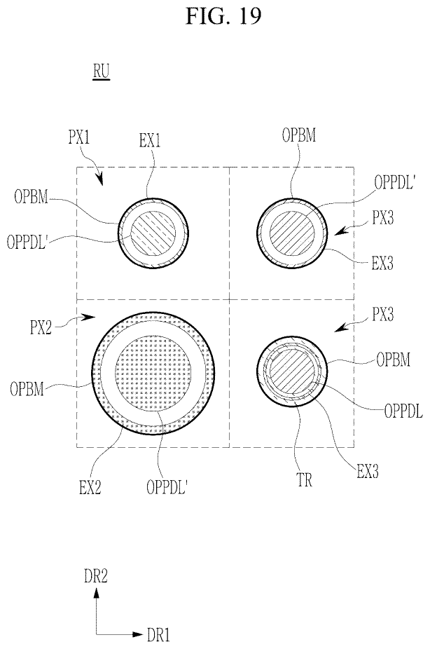

Referring to FIG. 19, according to an embodiment, the step difference structure TR may be applied to one of the third pixels PX3 in the first repeating unit RU. The step difference structure TR may not be applied to the first pixel PX1, the second pixel PX2, and the remaining one of the third pixels PX3. The first pixel PX1, the second pixel PX2, and the remaining one of the third pixels PX3 may have the cross-sectional structure shown in FIG. 14. The first pixel PX1, the second pixel PX2, and the remaining one of the third pixels PX3 may include the reflection regions EX1, EX2, and EX3 surrounding the pixel opening OPPDL′.

The third pixel PX3 to which the step difference structure TR is applied may include the reflection region EX3 surrounding the pixel opening OPPDL. A thickness of the reflection region EX3 of the third pixel PX3 to which the step difference structure TR is applied may be smaller than a thickness of the reflection region EX3 of the third pixel PX3 to which the step difference structure is not applied.

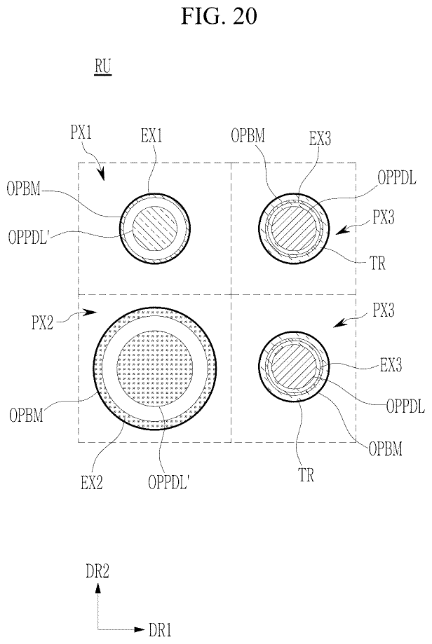

Referring to FIG. 20, according to an embodiment, the step difference structure TR may be applied to the third pixels PX3 in the first repeating unit RU. The step difference structure TR may not be applied to the first pixel PX1 and the second pixel PX2. The first pixel PX1 and the second pixel PX2 may have the cross-sectional structure shown in FIG. 14.

The first pixel PX1 and the second pixel PX2 may include the reflection regions EX1 and EX2 surrounding the pixel opening OPPDL′. The third pixel PX3 may include the reflection region EX3 surrounding the pixel opening OPPDL. A thickness of the reflection region EX3 formed in the third pixel PX3 to which the step difference structure TR is applied may be relatively small. The reflection region EX3 formed in the third pixel PX3 to which the step difference structure TR is applied may be formed relatively adjacent to the pixel opening OPPDL.

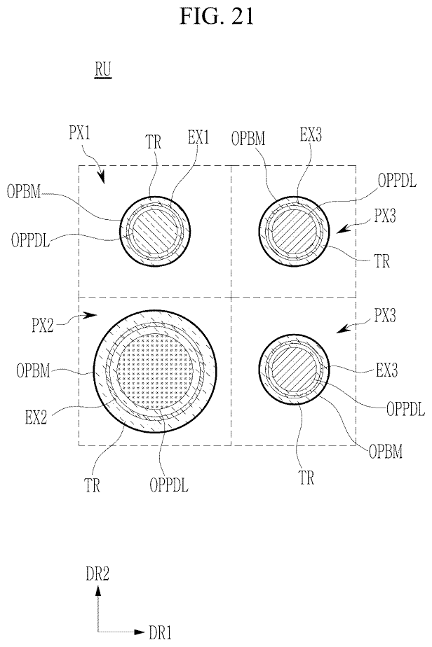

Referring to FIG. 21, according to an embodiment, the step difference structure TR may be applied to the first pixel PX1, the second pixel PX2, and the third pixels PX3 in the first repeating unit RU. The first pixel PX1, the second pixel PX2, and the third pixel PX3 may include the reflection regions EX1, EX2, and EX3 surrounding the pixel opening OPPDL.

The present specification describes one first repeating unit RU. In this case, the above description is not applied to all first repeating units, and the step difference structure may be applied only to at least some of the first repeating units RU among the plurality of first repeating units.

The display device according to an embodiment may reduce reflection of external light occurring in each pixel and may provide a color required by the user by applying the step difference structure TR to only a necessary pixel among the first pixel PX1, the second pixel PX2, and the third pixel PX3.

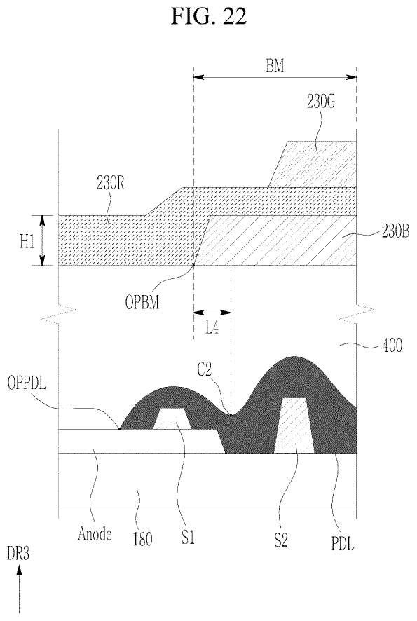

Hereinafter, a display device according to another embodiment will be described with reference to FIGS. 22 to 26. FIGS. 22 to 26 are schematic cross-sectional views of the display device according to another embodiment. A description of the same components as those described above will be omitted.

Referring to FIGS. 22 to 24, a description of the other components may be the same as that of the components according to the embodiments of FIGS. 6 to 8.

Referring to FIGS. 22 to 24, an area in which at least two color filters overlap to block visible light may be referred to as the light blocking area BM. In the embodiments of FIGS. 22 to 24, the blue color filter 230B, the red color filter 230R, and the green color filter 230G may be sequentially stacked. An order in which the color filters are stacked may vary according to an embodiment.

Referring to FIG. 22, in the pixel in which the red color filter 230R and the anode AE overlap, the light blocking area BM may be defined based on the blue color filter 230B. A distance L4 between an edge of the blue color filter 230B disposed on the light blocking area BM and the first concave portion C2 of the pixel defining layer PDL may be at least 1 micrometer. The first concave portion C2 may overlap the blue color filter 230B disposed on the light blocking area BM. An uneven upper surface of the pixel defining layer PDL may include a first high point P1, a second high point P2, and a first low point L1 therebetween. The first low point L1 may correspond to a lowest point or a lowest portion of the first concave portion C2. The first high point P1 may correspond to an uppermost point of a convex portion which is disposed on an upper surface of a first layer S1. The second high point P2 may correspond to an uppermost point of a convex portion which is disposed on an upper surface of a spacer S2. The distance L4 between the edge of the blue color filter 230B and the first low point L1 may be at least 1 micrometer when viewed in a plan view.

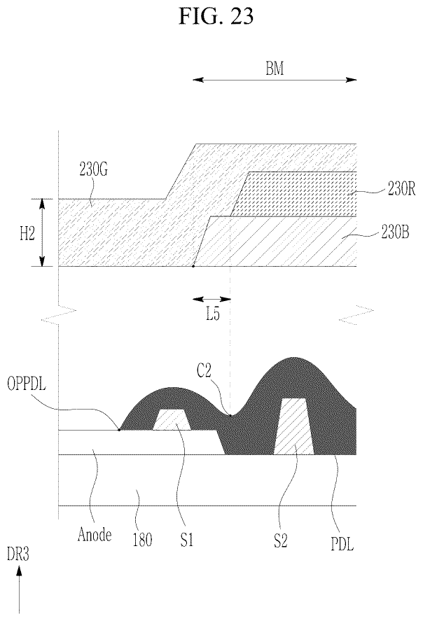

Referring to FIG. 23, in the pixel in which the green color filter 230G and the anode AE overlap, the light blocking area BM may be defined based on the blue color filter 230B. A distance L5 between the edge of the blue color filter 230B disposed on the light blocking area BM and the first concave portion C2 of the pixel defining layer PDL may be at least 1 micrometer. The first concave portion C2 may overlap the blue color filter 230B disposed on the light blocking area BM. In an embodiment, the distance L5 between the edge of the blue color filter 230B and the first low point L1 which is between the first high point P1 and the second high point P2 may be at least 1 micrometer when viewed in a plan view.

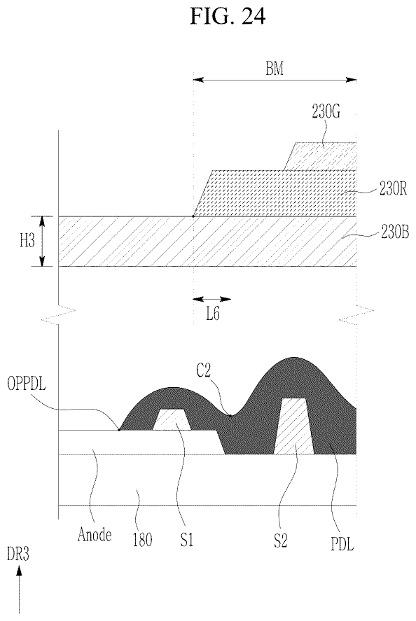

Referring to FIG. 24, in the pixel in which the blue color filter 230B and the anode AE overlap, the light blocking area BM may be defined based on the red color filter 230R. A distance L6 between an edge of the red color filter 230R disposed on the light blocking area BM and the first concave portion C2 of the pixel defining layer PDL may be at least 1 micrometer. The first concave portion C2 may overlap the red color filter 230R disposed on the light blocking area BM. In an embodiment, the distance L6 between the edge of the red color filter 230R and the first low point L1 which is between the first high point P1 and the second high point P2 may be at least 1 micrometer when viewed in a plan view.

Referring to FIGS. 22 to 24, the red color filter 230R may have a first height H1, the green color filter 230G may have a second height H2, and the blue color filter 230B may have a third height H3. The first height H1, the second height H2, and the third height H3 may be different from each other, and according to an embodiment, sizes of the second height H2, the first height H1 and the third height H3 may decrease in that order.

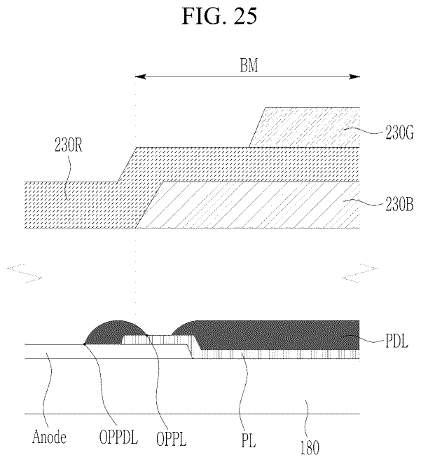

Referring to FIG. 25, the embodiment of FIG. 25 may include the same components as that of the embodiments of FIG. 9 and FIG. 10. Referring to FIG. 25, an area in which at least two color filters overlap to block visible light may be referred to as the light blocking area BM, and in the embodiment of FIG. 25, the blue color filter 230B, the red color filter 230R, and the green color filter 230G may be sequentially stacked in the light blocking area BM. An order in which the color filters are stacked may vary according to an embodiment.

As shown in FIG. 25, the second opening OPPL of the pixel defining layer PDL may be disposed inward from an edge of the color filter 230B that defines the light blocking area BM. Although the present specification illustrates the blue color filter 230B defining the light blocking area BM, the color filter defining the light blocking area BM may be the red color filter or the green color filter.

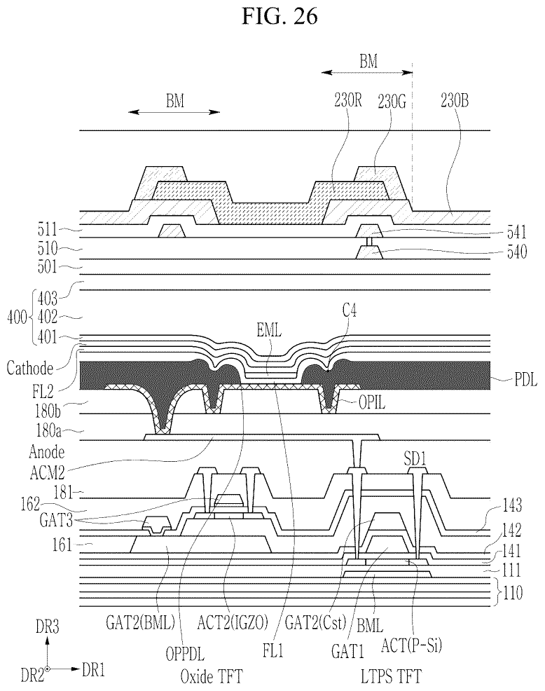

Referring to FIG. 26, the embodiment of FIG. 26 may include the same components as those of the embodiments of FIGS. 11A, 11B, and 12. Referring to FIG. 26, an area in which at least two color filters overlap to block visible light may be referred to as the light blocking area BM, and in the embodiment of FIG. 26, the blue color filter 230B, the red color filter 230R, and the green color filter 230G may be sequentially stacked. An order in which the color filters are stacked may vary according to an embodiment.

Referring to FIG. 26, the second concave portion C4 of the pixel defining layer PDL may be disposed inward from an edge of the blue color filter 230B defining the light blocking area BM. The second concave portion C4 may overlap the light blocking area BM. Although the present specification illustrates the blue color filter 230B defining the light blocking area BM, the color filter defining the light blocking area BM may be the red color filter or the green color filter.

The display device according to an embodiment may include the curve-shaped pixel defining layer PDL. When the cathode is formed on a flat surface of the pixel defining layer PDL, incident external light may be reflected from the flat surface to be emitted in a front direction, and the light may form a reflection region (or a reflection band). Because the reflected light is emitted toward the light blocking area, the curve-shaped pixel defining layer PDL according to an embodiment may reduce reflection of the external light. The pixel defining layer PDL may have a stably curved shape (i.e., the uneven upper surface) through a simple process.

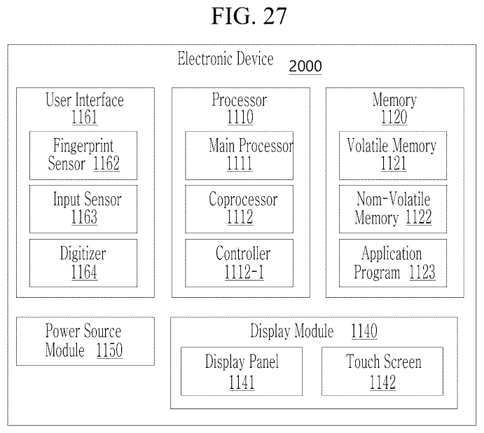

FIG. 27 is a diagram illustrating an electronic device according to an embodiment of the present invention. Referring to FIG. 27, the electronic device 2000 according to one embodiment of the present invention may output various information (e.g., images, text, music, etc.) through a display module 1140, which, for example, may correspond to the display device shown in FIG. 1. When a processor 1110 executes an application stored in a memory 1120, the display module 1140 may provide application information to a user through a display panel 1141.

In some embodiments, the electronic device 2000 may be configured as a smartphone, camera, smart TV, monitor, smartwatch, tablet, automotive display, or AR/VR headset. For example, the electronic device 2000 may be a smartphone including a touch-sensitive display area DA for interaction and a non-display area NDA including sensors and circuits for enhanced functionality. For example, the electronic device 2000 may be a television or monitor including a large display area DA for high-resolution video playback and a non-display area NDA incorporating driving circuits or connectivity modules for external inputs. For example, the electronic device 2000 may be a smartwatch including a display area DA optimized for compact and high-clarity visuals and a non-display area NDA integrating biometric sensors for health monitoring. In some cases, the electronic device 2000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 2000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 2000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 1.

The user interface 1161 serves as the interaction medium between a user and the electronic device 2000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 2000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 2000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

### DESCRIPTION OF SYMBOLS

SUB: substrate
AE: anode
PDL: pixel defining layer
EML: light emitting layer
CE: cathode
400: encapsulation layer
230R, 230G, 230B: color filter
220: light blocking layer

What is claimed is:

1. A display device comprising:
a substrate;
an anode disposed on the substrate;
a pixel defining layer provided with an opening exposing the anode, wherein an upper surface of the pixel defining layer includes a first high point, a second high point, and a low point therebetween, wherein the first high point and the second high point are higher than the low point;
a first layer disposed on an upper surface of the anode, wherein the first high point overlaps an upper surface of the first layer;
a light emitting layer disposed in the opening of the pixel defining layer;
a cathode disposed on the light emitting layer and the pixel defining layer; and
a light blocking area disposed on the pixel defining layer and overlapping the low point of the pixel defining layer.

2. The display device of claim 1,
wherein at least a portion of the first layer is spaced apart from the light blocking area when viewed in a plan view.

3. The display device of claim 1,
wherein the low point is disposed at least 1 micrometer from an inner edge of the light blocking area toward the second high point when viewed in a plan view.

4. The display device of claim 1, further comprising:
a spacer spaced apart from a sidewall of the anode,
wherein the second high point overlaps an upper surface of the spacer, and
wherein the spacer and the first layer are formed of the same material.

5. The display device of claim 4,
wherein the spacer and the first layer are disposed below the upper surface of the pixel defining layer.

6. The display device of claim 1,
wherein the light blocking area includes a light blocking opening,
wherein the first layer is formed of a closed loop with a first thickness when viewed in a plan view, and
wherein the opening, the closed loop of the first layer, and the light blocking opening are concentrically aligned when viewed in the plan view with the first layer surrounding the opening, and the light blocking opening surrounding the first layer.

7. The display device of claim 1, further comprising:
a red pixel, a green pixel, and a blue pixel disposed on the substrate,
wherein the first layer overlaps at least one of the red pixel, the green pixel, and the blue pixel.

8. The display device of claim 1,
wherein the light blocking area includes a light blocking layer including a light blocking material.

9. The display device of claim 1,
wherein the light blocking area corresponds to a region where at least two color filters of different colors overlap.

10. The display device of claim 1,
wherein the low point corresponds to a lowest portion of the upper surface of the pixel defining layer between the first high point and the second high point.

11. A display device comprising:
a substrate;
an anode disposed on the substrate;
a protective layer disposed on the anode;
a pixel defining layer overlapping the anode and provided with a first opening exposing the anode and a second opening exposing the protective layer;
a light emitting layer disposed within the first opening;
a cathode disposed on the light emitting layer and the pixel defining layer; and
a light blocking area disposed on the pixel defining layer and overlapping an exposed portion of the protective layer by the second opening.

12. The display device of claim 11,
wherein the light blocking area includes a light blocking opening,
wherein the second opening is formed of a closed loop with a first thickness when viewed in a plan view, and
wherein the first opening, the light blocking opening, and the closed loop of the second opening are concentrically arranged when viewed in the plan view, with the light blocking opening surrounding the first opening, and the closed loop of the second opening surrounding the light blocking opening.

13. The display device of claim 11, further comprising:
a red pixel, a green pixel, and a blue pixel disposed on the substrate,
wherein the exposed portion of the protective layer overlaps at least one of the red pixel, the green pixel, and the blue pixel.

14. The display device of claim 11,
wherein the light blocking area corresponds to a region where at least two color filters of different colors overlap.

15. An electronic device, comprising:
a processor;
a memory having stored application programs for execution by the processor;
a display device comprising:
a substrate;
a first insulating layer disposed on the substrate;
a second insulating layer disposed on the substrate and provided with an opening exposing the first insulating layer;
an anode including a first portion disposed on an upper surface of the second insulating layer and a second portion disposed in the opening of the second insulating layer;
a pixel defining layer provided with a first opening exposing the first portion of the anode and disposed on the second portion of the anode, wherein an upper surface of the pixel defining layer includes a first high point, a second high point, and a low point disposed therebetween;
a light emitting layer disposed within the first opening of the pixel defining layer;
a cathode disposed on the light emitting layer and the pixel defining layer; and
a light blocking area disposed on the pixel defining layer and overlapping the low point of the pixel defining layer.

16. The electronic device of claim 15,
wherein the low point is disposed at least 1 micrometer from an inner edge of the light blocking area toward the second high point when viewed in a plan view.

17. The electronic device of claim 15,
wherein the light blocking area includes a light blocking opening,
wherein the low point is formed of a closed loop when viewed in a plan view, and
wherein the first opening, the light blocking opening, and the closed loop of the second high point are concentrically arranged when viewed in the plan view, with the light blocking opening surrounding the first opening, and the closed loop of the second high point surrounding the light blocking opening.

18. The electronic device of claim 15, further comprising:
a red pixel, a green pixel, and a blue pixel disposed on the substrate,
wherein the opening of the second insulating layer and the low point overlap at least one of the red pixel, the green pixel, and the blue pixel.

19. The electronic device of claim 15,
wherein the light blocking area corresponds to a region where at least two color filters of different colors overlap.

20. The electronic device of claim 15,
wherein the low point corresponds to a lowest portion of the upper surface of the pixel defining layer between the first high point and the second high point.
